(19) United States
(12) Patent Application Publication
(10) Pub. No.: US 2026/0177922 A1
(43) Pub. Date: Jun. 25, 2026

(54) UNDERLAYER FILM MATERIAL FOR SELF-ASSEMBLED FILM

(71) Applicant: NISSAN CHEMICAL CORPORATION, Tokyo (JP)

(72) Inventors: Ryuta MIZUOCHI, Toyama-shi (JP); Tomotada HIROHARA, Toyama-shi (JP); Mamoru TAMURA, Toyama-shi (JP)

(73) Assignee: NISSAN CHEMICAL CORPORATION, Tokyo (JP)

(21) Appl. No.: 19/128,737

(22) PCT Filed: Nov. 16, 2023
(86) PCT No.: PCT/JP2023/041178

§ 371 Date: May 9, 2025

(30) Foreign Application Priority Data
Nov. 17, 2022 (JP) 2022-184266

(51) Int. Cl. G03F 7/20; G03F 7/00; G03F 7/11

(52) U.S. Cl. CPC G03F 7/20; G03F 7/0002; G03F 7/11

(57) ABSTRACT

An underlayer film, which is a baked product of a coating film of an underlayer film-forming composition, in which in lithography using a resist film of either a photoresist film or an electron beam resist film and a self-assembled film, the underlayer film is used as an underlayer film of the resist film, and then is further used as an underlayer film of the self-assembled film, the underlayer film-forming composition contains a polymer and a crosslinking agent, the polymer has a unit structure (A) having a polycyclic aromatic structure and a unit structure (B) having a reactive group, and the crosslinking agent has a functional group that can react with the reactive group.

### TECHNICAL FIELD

The present invention relates to an underlayer film-forming composition and an underlayer film used for lithography using a resist film and a self-assembled film, and a method for producing a semiconductor element using the same.

### BACKGROUND ART

In recent years, in accordance with further miniaturization of a large-scale integrated circuit (LSI), a technique for processing a finer structure has been required. In response to such a demand, an attempt has been made to form a finer pattern using a phase separation structure formed by self-assembly of a block copolymer in which incompatible polymers are bonded to each other. For example, a pattern forming method, in which an underlayer film-forming composition is applied onto a substrate to form an underlayer film formed of the composition, a self-assembled film containing a block copolymer in which two or more types of polymers are bonded to each other is formed on a surface of the underlayer film, the block copolymer in the self-assembled film is subjected to phase separation, and a phase of at least one type of polymers included in the block copolymer is selectively removed, has been proposed.

Patent Literature 1 discloses a primer containing a resin component in which 20 mol % to 80 mol % of structural units of the entire components are structural units derived from an aromatic ring-containing monomer.

Patent Literature 2 discloses an underlayer film-forming composition of a self-assembled film containing a polymer having a unit structure of an aromatic vinyl compound which may be substituted, such as styrene, vinylnaphthalene, acenaphthylene, or vinylcarbazole, in an amount of 20 mol % or more with respect to all unit structures of the polymer and having a unit structure of a polycyclic aromatic vinyl compound in an amount of 1 mol % or more with respect to all unit structures of the aromatic vinyl compound.

### CITATION LIST

### Patent Literature

Patent Literature 1: WO 2012/036121 A
Patent Literature 2: WO 2014/097993 A

### SUMMARY OF INVENTION

### Technical Problem

When microfabrication is performed using a self-assembled film, a resist (a photoresist or an electron beam resist) used in conventional microfabrication may be used in combination. In that case, when an underlayer film of the resist film also serves as an underlayer film of the self-assembled film, the underlayer film is required not to increase the roughness of the resist pattern and to be able to form a vertical alignment in the self-assembled film.

An object of the present invention is to provide an underlayer film that serves as both an underlayer film of a resist film and an underlayer film of a self-assembled film, can improve the roughness of a resist pattern, and can form a vertical alignment in the self-assembled film, an underlayer film-forming composition capable of forming the underlayer film, and a method for producing a semiconductor element using the underlayer film-forming composition.

### Solution to Problem

As a result of intensive studies to solve the above problem, the present inventors have found that the above problem can be solved, and have completed the present invention having the following gist.

That is, the present invention includes the following.

[1] An underlayer film, which is a baked product of a coating film of an underlayer film-forming composition, wherein
in lithography using a resist film of either a photoresist film or an electron beam resist film and a self-assembled film, the underlayer film is used as an underlayer film of the resist film, and then is further used as an underlayer film of the self-assembled film,
the underlayer film-forming composition contains a polymer and a crosslinking agent,
the polymer has a unit structure (A) having a polycyclic aromatic structure and a unit structure (B) having a reactive group, and
the crosslinking agent has a functional group that can react with the reactive group.
   [2] The underlayer film according to [1], wherein the unit structure (A) is a unit structure represented by formula (A-1) below:

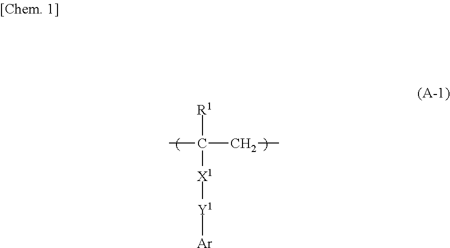

in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted.
   [3] The resist underlayer film according to [1] or [2], wherein the unit structure (B) is at least one of a unit structure represented by formula (B-1) below and a unit structure represented by formula (B-2) below:

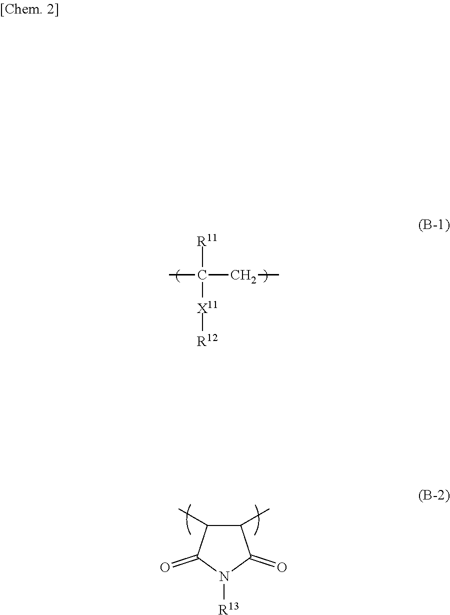

in formula (B-1), R¹¹ represents a hydrogen atom or a methyl group, X¹¹ represents an ester group or an amide group, and R¹² represents a monovalent group having 1 to 12 carbon atoms and having the reactive group, and
in formula (B-2), R¹³ represents a monovalent group having 1 to 12 carbon atoms and having the reactive group.
   [4] The underlayer film according to any one of [1] to [3], wherein the polymer further has a unit structure (C) of at least one of a unit structure (C-1) having a monocyclic aromatic structure and a unit structure (C-2) derived from a maleimide structure.
   [5] The underlayer film according to [4], wherein
the unit structure (C-1) is a unit structure represented by formula (C-1-1) below, and
the unit structure (C-2) is a unit structure represented by formula (C-2-1) below:

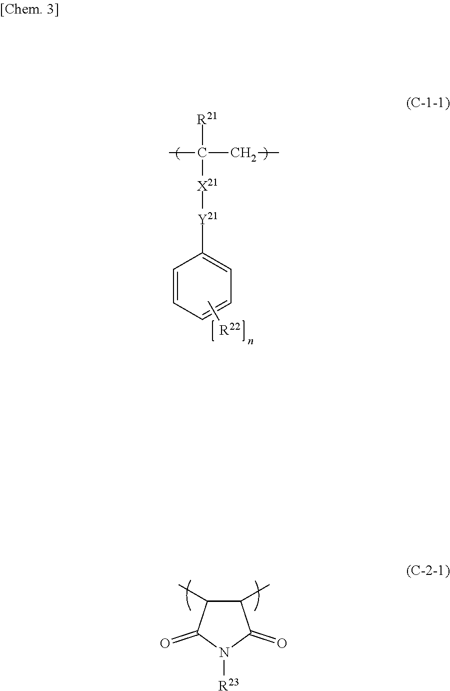

in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.
   [6] The underlayer film according to any one of [1] to [5], wherein a molar ratio of the unit structure (A) to all unit structures of the polymer is 40 mol % or more.
   [7] The underlayer film according to any one of [1] to [6], wherein a molar ratio of the unit structure (B) to all unit structures of the polymer is 5 mol % to 40 mol %.
   [8] The underlayer film according to [1], wherein
the polymer further has a unit structure (C) of at least one of a unit structure (C-1) having a monocyclic aromatic structure and a unit structure (C-2) derived from a maleimide structure,
the unit structure (A) is a unit structure represented by formula (A-1) below,
the unit structure (B) is at least one of a unit structure represented by formula (B-1) below and a unit structure represented by formula (B-2) below,
the unit structure (C-1) is a unit structure represented by formula (C-1-1) below,
the unit structure (C-2) is a unit structure represented by formula (C-2-1) below,
a molar ratio of the unit structure (A) to all unit structures of the polymer is 40 mol % or more, and
a molar ratio of the unit structure (B) to all unit structures of the polymer is 5 mol % to 40 mol %:

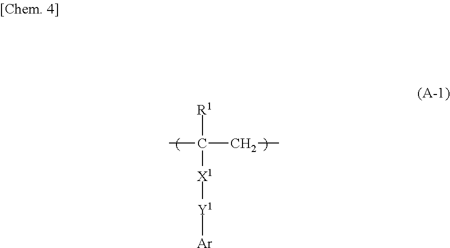

in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted,

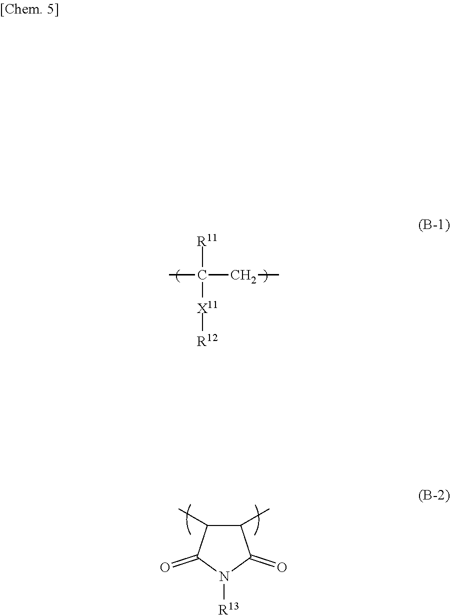

in formula (B-1), R¹¹ represents a hydrogen atom or a methyl group, X¹¹ represents an ester group or an amide group, and R¹² represents a monovalent group having 1 to 6 carbon atoms and having the reactive group, and
in formula (B-2), R¹³ represents a monovalent group having 1 to 6 carbon atoms and having the reactive group,

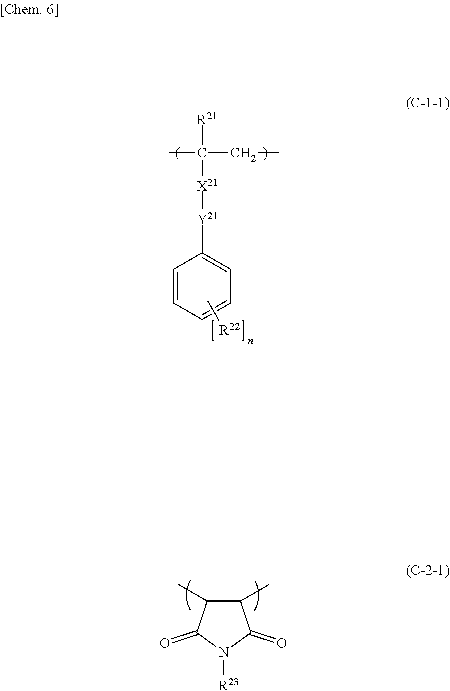

in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.
   [9] The underlayer film according to any one of [1] to [8], wherein a content of the crosslinking agent in the underlayer film-forming composition is 20 mass % to 50 mass % of the polymer.
   [10] The underlayer film according to any one of [1] to [9], wherein the self-assembled film is a film containing a block copolymer.
   [11] The underlayer film according to any one of [1] to [10], wherein a film thickness is less than 10 nm.
   [12] An underlayer film-forming composition for forming an underlayer film that is used, in lithography using a resist film of either a photoresist film or an electron beam resist film and a self-assembled film, as an underlayer film of the resist film, and then is further used as an underlayer film of the self-assembled film,
the underlayer film-forming composition containing a polymer and a crosslinking agent, wherein
the polymer has a unit structure (A) having a polycyclic aromatic structure and a unit structure (B) having a reactive group, and
the crosslinking agent has a functional group that can react with the reactive group.
   [13] The underlayer film-forming composition according to [12], wherein the unit structure (A) is a unit structure represented by formula (A-1) below:

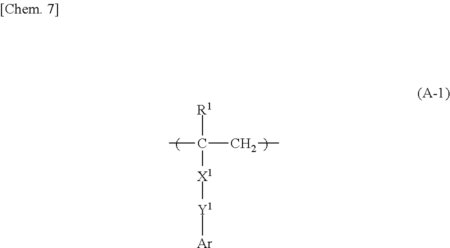

in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted.
   [14] The underlayer film-forming composition according to [12] or [13], wherein the unit structure (B) is at least one of a unit structure represented by formula (B-1) below and a unit structure represented by formula (B-2) below:

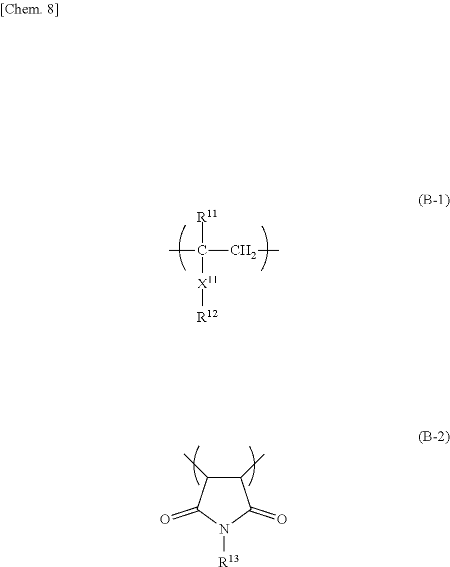

in formula (B-1), R¹¹ represents a hydrogen atom or a methyl group, X¹¹ represents an ester group or an amide group, and R¹² represents a monovalent group having 1 to 12 carbon atoms and having the reactive group, and
in formula (B-2), R¹³ represents a monovalent group having 1 to 12 carbon atoms and having the reactive group.
   [15] The underlayer film-forming composition according to any one of [12] to [14], wherein the polymer further has a unit structure (C) of at least one of a unit structure (C-1) having a monocyclic aromatic structure and a unit structure (C-2) derived from a maleimide structure.
   [16] The underlayer film-forming composition according to [15], wherein
the unit structure (C-1) is a unit structure represented by formula (C-1-1) below, and
the unit structure (C-2) is a unit structure represented by formula (C-2-1) below:

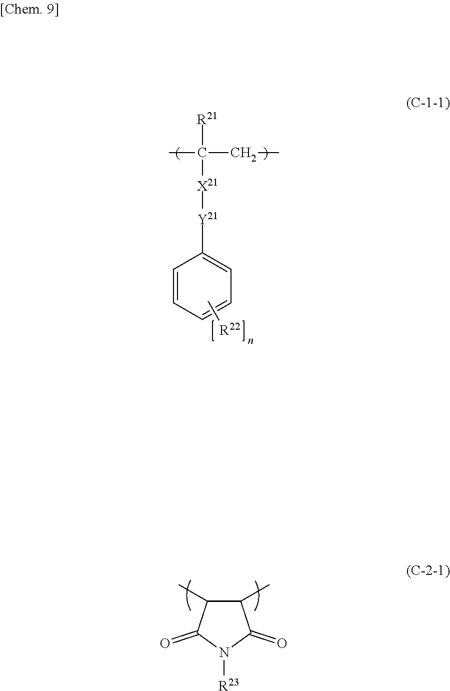

in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.
   [17] The underlayer film-forming composition according to any one of [12] to [16], wherein a molar ratio of the unit structure (A) to all unit structures of the polymer is 40 mol % or more.
   [18] The underlayer film-forming composition according to any one of [12] to [17], wherein a molar ratio of the unit structure (B) to all unit structures of the polymer is 5 mol % to 40 mol %.
   [19] The underlayer film-forming composition according to [12], wherein
the polymer further has a unit structure (C) of at least one of a unit structure (C-1) having a monocyclic aromatic structure and a unit structure (C-2) derived from a maleimide structure,
the unit structure (A) is a unit structure represented by formula (A-1) below,
the unit structure (B) is at least one of a unit structure represented by formula (B-1) below and a unit structure represented by formula (B-2) below,
the unit structure (C-1) is a unit structure represented by formula (C-1-1) below,
the unit structure (C-2) is a unit structure represented by formula (C-2-1) below,
a molar ratio of the unit structure (A) to all unit structures of the polymer is 40 mol % or more, and
a molar ratio of the unit structure (B) to all unit structures of the polymer is 5 mol % to 40 mol %:

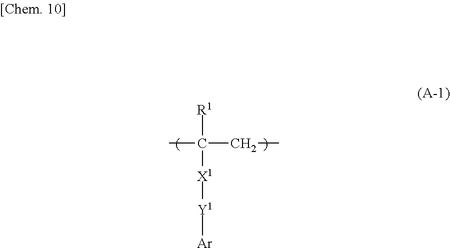

in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted,

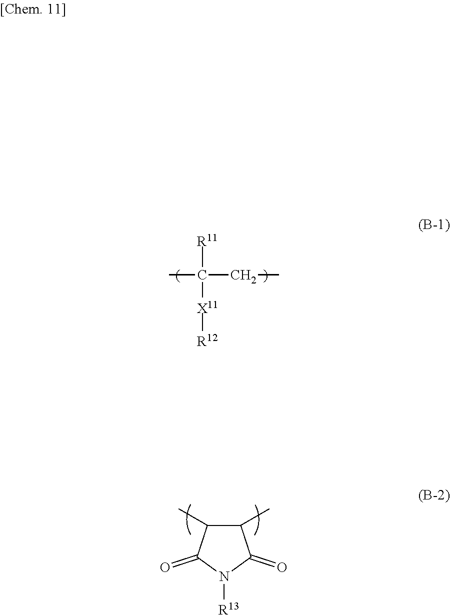

in formula (B-1), R¹¹ represents a hydrogen atom or a methyl group, X¹¹ represents an ester group or an amide group, and R¹² represents a monovalent group having 1 to 6 carbon atoms and having the reactive group, and
in formula (B-2), R¹³ represents a monovalent group having 1 to 6 carbon atoms and having the reactive group,

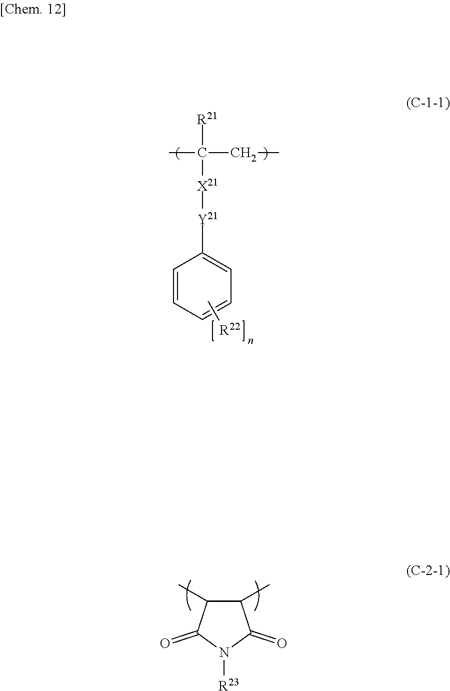

in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.
   [20] The underlayer film-forming composition according to any one of [11] to [19], wherein a content of the crosslinking agent is 20 mass % to 50 mass % of the polymer.
   [21] The underlayer film-forming composition according to any one of [12] to [20], wherein the self-assembled film is a film containing a block copolymer.
   [22] The underlayer film-forming composition according to any one of [12] to [21], wherein a film thickness of the underlayer film is less than 10 nm.
   [23] A method for producing a semiconductor element, the method comprising:
a step of forming an underlayer film on a semiconductor substrate using the underlayer film-forming composition according to any one of [12] to [22];
a step of forming a resist film of either a photoresist film or an electron beam resist film on the underlayer film;
a step of obtaining a resist pattern by irradiating the resist film with light or an electron beam, and then developing the resist film;
a step of forming a patterned underlayer film by etching the underlayer film using the resist pattern as a mask; and
a step of forming a self-assembled film on the patterned underlayer film.
   [24] The method for producing a semiconductor element according to [23], further comprising a step of forming a brush layer in a gap in a pattern of the patterned underlayer film between the step of forming a patterned underlayer film and the step of forming a self-assembled film.
   [25] The method for producing a semiconductor element according to [23], or [24] wherein the self-assembled film is a film containing a block copolymer.
   [26] The method for producing a semiconductor element according to any one of [23] to [25], further comprising a step of removing the resist pattern after the step of forming a patterned underlayer film.

### Advantageous Effects of Invention

According to the present invention, it is possible to provide an underlayer film that serves as both an underlayer film of a resist film and an underlayer film of a self-assembled film, can improve the roughness of a resist pattern, and can form a vertical alignment in the self-assembled film, an underlayer film-forming composition capable of forming the underlayer film, and a method for producing a semiconductor element using the underlayer film-forming composition.

### BRIEF DESCRIPTION OF DRAWINGS

FIG. 1A is a schematic cross-sectional view for explaining an example of a method for producing a semiconductor element of the present invention (part 1).

FIG. 1B is a schematic cross-sectional view for explaining an example of a method for producing a semiconductor element of the present invention (part 2).

FIG. 1C is a schematic cross-sectional view for explaining an example of a method for producing a semiconductor element of the present invention (part 3).

FIG. 1D is a schematic cross-sectional view for explaining an example of a method for producing a semiconductor element of the present invention (part 4).

FIG. 1E is a schematic cross-sectional view for explaining an example of a method for producing a semiconductor element of the present invention (part 5).

FIG. 1F is a schematic cross-sectional view for explaining an example of a method for producing a semiconductor element of the present invention (part 6).

FIG. 1G is a schematic cross-sectional view for explaining an example of a method for producing a semiconductor element of the present invention (part 7).

FIG. 1H is a schematic cross-sectional view for explaining an example of a method for producing a semiconductor element of the present invention (part 8).

FIG. 1I is a schematic cross-sectional view for explaining an example of a method for producing a semiconductor element of the present invention (part 9).

FIG. 2A is an electron microscope (SEM) photograph of a microphase separation structure of a self-assembled film prepared using a self-assembled film-forming composition 1 in Example 1.

FIG. 2B is an SEM photograph of a microphase separation structure of a self-assembled film prepared using a self-assembled film-forming composition 2 in Example 1.

FIG. 3A is an SEM photograph of a microphase separation structure of a self-assembled film prepared using the self-assembled film-forming composition 1 in Example 2.

FIG. 3B is an SEM photograph of a microphase separation structure of a self-assembled film prepared using the self-assembled film-forming composition 2 in Example 2.

FIG. 4A is an SEM photograph of a microphase separation structure of a self-assembled film prepared using the self-assembled film-forming composition 1 in Comparative Example 1.

FIG. 4B is an SEM photograph of a microphase separation structure of a self-assembled film prepared using the self-assembled film-forming composition 2 in Comparative Example 1.

### DESCRIPTION OF EMBODIMENTS

An underlayer film of the present invention is a baked product of a coating film of an underlayer film-forming composition. Therefore, after the underlayer film-forming composition is described, the underlayer film of the present invention will be described.

### (Underlayer Film-Forming Composition)

The underlayer film-forming composition of the present invention is an underlayer film-forming composition for forming an underlayer film.

The underlayer film is an underlayer film that is used, in lithography using a resist film of either a photoresist film or an electron beam resist film and a self-assembled film, as an underlayer film of the resist film, and then further used as an underlayer film of the self-assembled film.

The underlayer film-forming composition of the present invention contains a polymer and a crosslinking agent.

The polymer has a unit structure (A) having a polycyclic aromatic structure and a unit structure (B) having a reactive group.

The crosslinking agent has a functional group that can react with a reactive group.

When the underlayer film-forming composition contains a polymer and a crosslinking agent, the polymer has a unit structure (A) having a polycyclic aromatic structure and a unit structure (B) having a reactive group, and the crosslinking agent has a functional group that can react with the reactive group, it is possible to form an underlayer film which serves as both an underlayer film of a resist film and an underlayer film of a self-assembled film, can improve the roughness of a resist pattern, and can form a vertical alignment in the self-assembled film.

### <Polymer>

The polymer has a unit structure (A) having a polycyclic aromatic structure and a unit structure (B) having a reactive group. Hereinafter, this polymer is sometimes referred to as a “specific polymer”.

### <<Unit Structure (A)>>

The unit structure (A) is a unit structure having a polycyclic aromatic structure.

In the present description, the polycyclic aromatic structure is a structure formed of two or more aromatic rings exhibiting aromaticity, and includes a fused polycyclic aromatic structure having a fused ring and an aromatic ring assembly structure in which a plurality of aromatic rings are directly bonded through a single bond.

The polycyclic aromatic structure may be a structure formed only of a hydrocarbon or a structure having a hetero atom (for example, an oxygen atom, a nitrogen atom, or a sulfur atom).

The fused polycyclic aromatic structure is not particularly limited, and examples thereof include a naphthalene structure, an anthracene structure, a phenanthrene structure, a pyrene structure, a triphenylene structure, a chrysene structure, a naphthacene structure, a biphenylene structure, and a fluorene structure.

The aromatic ring assembly structure is not particularly limited, and examples thereof include a carbazole structure, a biphenyl structure, a terphenyl structure, a quaterphenyl structure, a binaphthalene structure, a phenylnaphthalene structure, a phenylfluorene structure, and a diphenylfluorene structure.

The polycyclic aromatic structure may be substituted with a substituent. The substituent which may be substituted is not particularly limited, and examples thereof include a halogen atom, a hydroxy group, an alkyl group, an alkoxy group, a thiol group, a cyano group, a carboxy group, an amino group, an amide group, an alkoxycarbonyl group, and a thioalkyl group.

Examples of the halogen atom include a fluorine atom, a chlorine atom, a bromine atom, and an iodine atom.

Examples of the alkyl group include an alkyl group having 1 to 6 carbon atoms. Examples of the alkyl group having 1 to 6 carbon atoms include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group. Further, a cyclic alkyl group can also be used as the alkyl group, and examples of a cyclic alkyl group having 1 to 10 carbon atoms include a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Examples of the alkoxy group include an alkoxy group having 1 to 6 carbon atoms. Examples of the alkoxy group having 1 to 6 carbon atoms include a methoxy group, an ethoxy group, and an isopropoxy group.

Examples of the amide group include an amide group having 1 to 12 carbon atoms. Examples of the amide group having 1 to 12 carbon atoms include a formamide group, an acetamide group, a propionamide group, an isobutyramide group, a benzamide group, a naphthylamide group, and an acrylamide group.

Examples of the alkoxycarbonyl group include an alkoxycarbonyl group having 2 to 12 carbon atoms. Examples of the alkoxycarbonyl group having 2 to 12 carbon atoms include a methoxycarbonyl group, an ethoxycarbonyl group, and a benzyloxycarbonyl group.

Examples of the thioalkyl group include a thioalkyl group having 1 to 6 carbon atoms. Examples of the thioalkyl group having 1 to 6 carbon atoms include a methylthio group, an ethylthio group, a butylthio group, and a hexylthio group.

From the viewpoint of suitably obtaining the effect of the present invention, the polycyclic aromatic structure is preferably a naphthalene structure, an anthracene structure, a phenanthrene structure, a pyrene structure, a triphenylene structure, a chrysene structure, a naphthacene structure, a biphenylene structure, a fluorene structure, or a carbazole structure, more preferably a naphthalene structure, an anthracene structure, a phenanthrene structure, a pyrene structure, or a carbazole structure, and still more preferably a naphthalene structure or a carbazole structure.

The polycyclic aromatic structure may be of one type or two or more types, but is preferably of one type or two types.

The unit structure (A) is not particularly limited, but a unit structure represented by formula (A-1) below is preferable from the viewpoint of suitably obtaining the effect of the present invention.

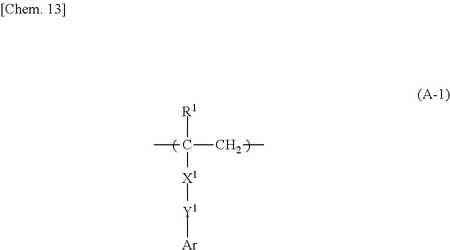

In formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted.

Examples of the substituent that Ar may have include a halogen atom, a hydroxy group, an alkyl group, an alkoxy group, a thiol group, a cyano group, a carboxy group, an amino group, an amide group, an alkoxycarbonyl group, and a thioalkyl group.

The unit structure represented by formula (A-1) is not particularly limited, but a unit structure represented by formula (A-1-1) below is preferable from the viewpoint of suitably obtaining the effect of the present invention.

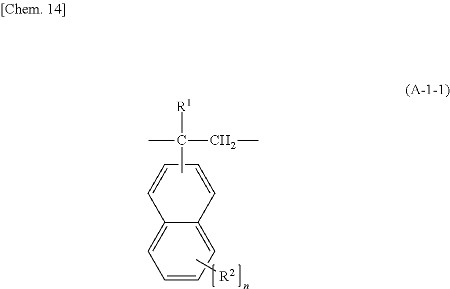

In formula (A-1-1), R¹ represents a hydrogen atom or a methyl group, R² represents a halogen atom, a hydroxy group, an alkyl group, an alkoxy group, a thiol group, a cyano group, a carboxy group, an amino group, an amide group, an alkoxycarbonyl group, or a thioalkyl group, n represents an integer of 0 to 7, and when there are two or more R²'s, the two or more R²'s may be identical or different.

Examples of the unit structure represented by formula (A-1) include the following unit structures.

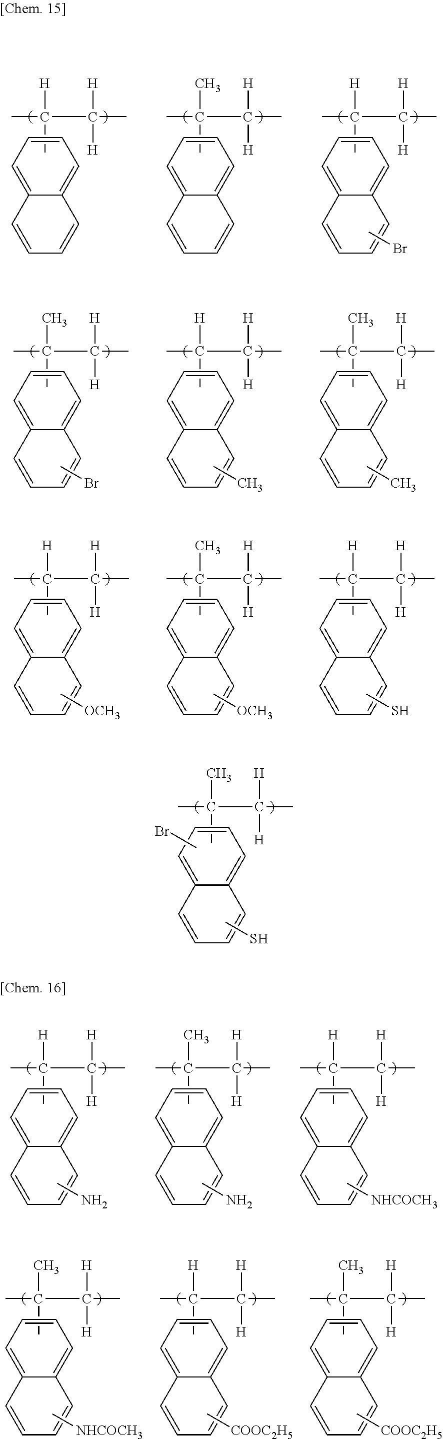

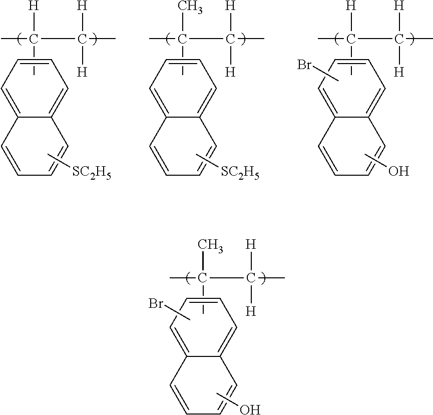

The unit structure (A) in the specific polymer may be of one type or two or more types, but is preferably of one type or two types.

### <<Unit Structure (B)>>

The unit structure (B) is a unit structure having a reactive group.

The unit structure (B) is a structure different from the unit structure (A). For example, the unit structure (B) does not have a polycyclic aromatic structure.

The reactive group of the unit structure (B) is not particularly limited, and examples thereof include a hydroxy group, an epoxy group, an acyl group, an acetyl group, a formyl group, a benzoyl group, a carboxy group, a carbonyl group, an amino group, an imino group, a cyano group, an azo group, an azide group, a thiol group, a sulfo group, and an allyl group.

The unit structure (B) is not particularly limited, and is preferably at least either of a unit structure represented by formula (B-1) below and a unit structure represented by formula (B-2) below from the viewpoint of suitably obtaining the effect of the present invention.

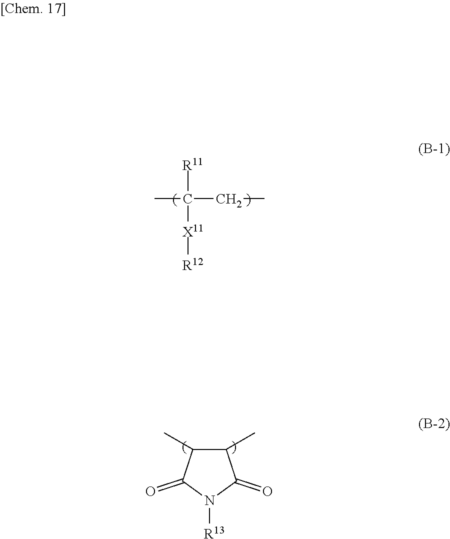

In formula (B-1), R¹¹ represents a hydrogen atom or a methyl group, X¹¹ represents an ester group or an amide group, and R¹² represents a monovalent group having 1 to 12 carbon atoms and having a reactive group.

In formula (B-2), R¹³ represents a monovalent group having 1 to 12 carbon atoms and having a reactive group.

Examples of the monovalent group having 1 to 12 carbon atoms and having a reactive group in R¹² and R¹³ include a hydroxyalkyl group having 1 to 12 carbon atoms.

Examples of the hydroxyalkyl group having 1 to 12 carbon atoms include a hydroxyalkyl group having 1 to 6 carbon atoms.

Examples of the hydroxyalkyl group having 1 to 12 carbon atoms include a hydroxymethyl group, a 1-hydroxyethyl group, a 2-hydroxyethyl group, a 1-hydroxypropyl group, a 2-hydroxypropyl group, a 3-hydroxypropyl group, a 1-hydroxybutyl group, a 2-hydroxybutyl group, a 3-hydroxybutyl group, a 4-hydroxybutyl group, a hydroxycyclohexyl group, a dihydroxycyclohexyl group, and a 3-hydroxy-1-adamantyl group.

The number of hydroxy groups of the hydroxyalkyl group having 1 to 12 carbon atoms may be 1 or 2 or more.

Examples of the unit structure represented by formula (B-1) include a unit structure represented by formula (B-1-1) below.

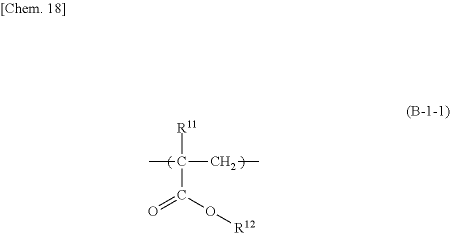

In formula (B-1-1), R¹¹ and R¹² have the same meanings as R¹¹ and R¹² in formula (B-1), respectively.

Examples of the unit structure represented by formula (B-1) include the following unit structures.

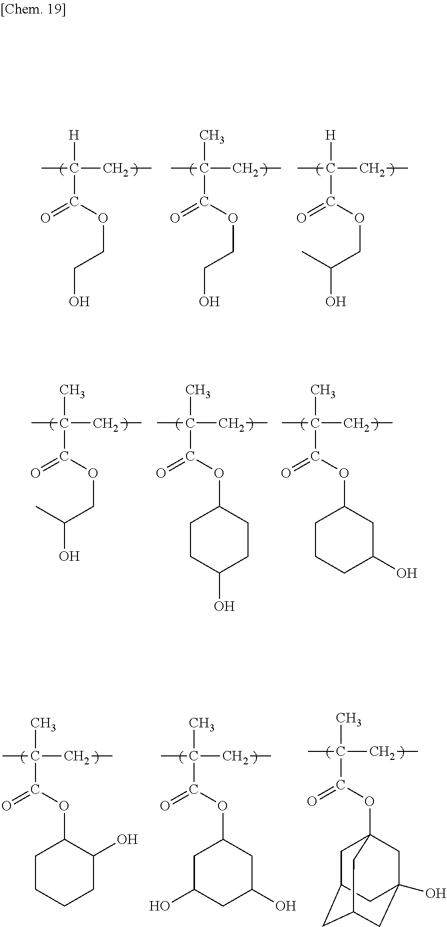

Examples of the unit structure represented by formula (B-2) include the following unit structures.

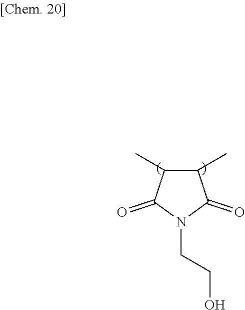

Examples of the unit structure containing an epoxy group as the reactive group include unit structures derived from compounds represented by general formulae (I) to (XVII) described in JP 2012-62365 A.

The unit structure (B) in the specific polymer may be of one type or two or more types, but is preferably of one type or two types.

### <<Unit Structure (C)>>

The specific polymer may have a unit structure other than the unit structure (A) and the unit structure (B). As such a unit structure, from the viewpoint of suitably obtaining the effect of the present invention, a unit structure (C) of at least either of a unit structure (C-1) having a monocyclic aromatic structure and a unit structure (C-2) derived from a maleimide structure is preferable.

The unit structure (C) is a unit structure different from the unit structure (A) and the unit structure (B).

For example, the unit structure (C) does not have a polycyclic aromatic structure and the reactive group of the unit structure (B).

The monocyclic aromatic ring of the unit structure (C-1) may be an aromatic hydrocarbon ring or an aromatic heterocyclic ring, but is preferably an aromatic hydrocarbon ring. Examples of such an aromatic hydrocarbon ring include a benzene ring.

The unit structure (C) is not particularly limited, and is preferably at least either of a unit structure represented by formula (C-1-1) below and a unit structure represented by formula (C-2-1) below from the viewpoint of suitably obtaining the effect of the present invention.

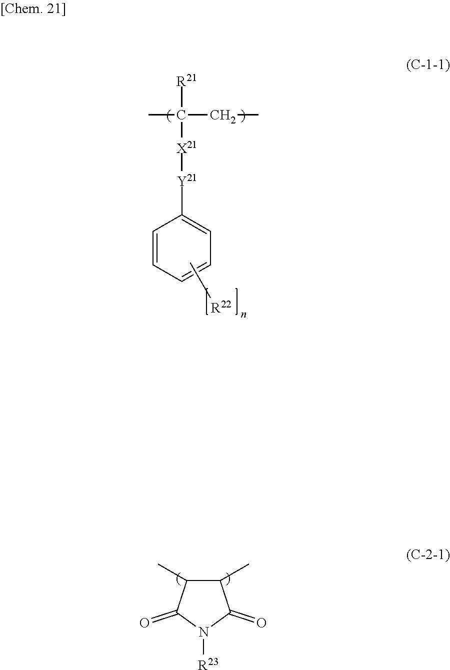

In formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different.

In formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.

Examples of the unit structure represented by formula (C-1-1) include a unit structure represented by formula (C-1-1-1) below and a unit structure represented by formula (C-1-1-2) below.

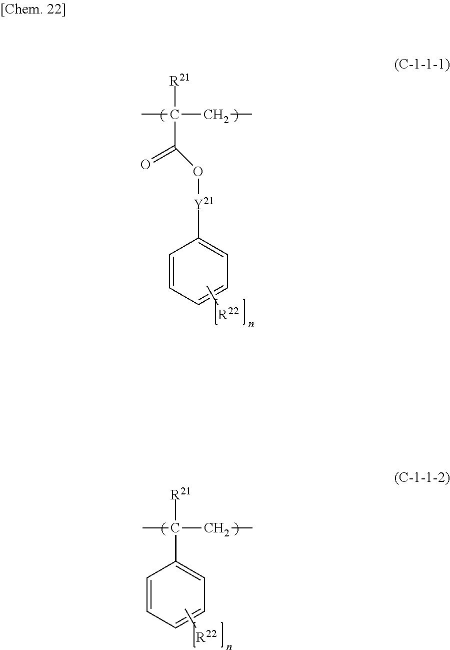

In formula (C-1-1-1) and formula (C-1-1-2), R²¹'s each independently represent a hydrogen atom or a methyl group, Y²¹ represents a single bond or an alkylene group having 1 to 6 carbon atoms, R²²'s each independently represent a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different.

In formula (C-1-1-2), n is preferably an integer of 1 to 5.

Examples of the unit structure represented by formula (C-1-1) include the following unit structures.

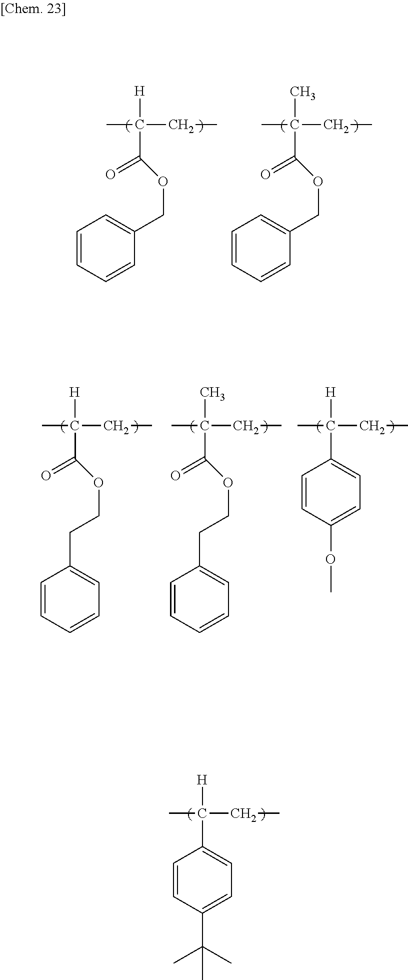

Examples of the unit structure represented by formula (C-2-1) include the following unit structures.

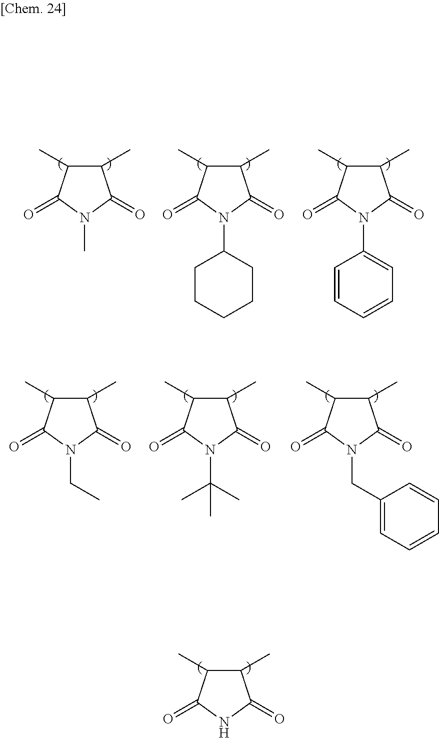

The unit structure (C) in the specific polymer may be of one type or two or more types, but is preferably of one type or two types.

The molar ratio of the unit structure (A) to all unit structures of the specific polymer is not particularly limited, and is preferably 40 mol % or more, more preferably 45 mol % or more, and particularly preferably 50 mol % or more from the viewpoint of suitably obtaining the effect of the present invention.

The molar ratio of the unit structure (A) to all unit structures of the specific polymer is preferably 95 mol % or less, more preferably 90 mol % or less, and particularly preferably 80 mol % or less.

The molar ratio of the unit structure (B) to all unit structures of the specific polymer is not particularly limited, and is preferably 5 mol % or more, more preferably 10 mol % or more, and particularly preferably 15 mol % or more from the viewpoint of suitably obtaining the effect of the present invention.

The molar ratio of the unit structure (B) to all unit structures of the specific polymer is preferably 40 mol % or less, more preferably 35 mol % or less, and particularly preferably 30 mol % or less.

When the specific polymer has the unit structure (C), the molar ratio of the unit structure (C) to all unit structures of the specific polymer is not particularly limited, and is preferably 5 mol % or more, more preferably 10 mol % or more, and particularly preferably 15 mol % or more from the viewpoint of suitably obtaining the effect of the present invention.

The molar ratio of the unit structure (C) to all unit structures of the specific polymer is preferably 40 mol % or less, more preferably 35 mol % or less, and particularly preferably 30 mol % or less.

The molar ratio of the unit structure (A) to the unit structure (B) (unit structure (A)/unit structure (B)) in the specific polymer is not particularly limited, and is preferably 1 to 9, and more preferably 1.5 to 5.

The distribution of the unit structure in the specific polymer is not particularly limited. The specific polymer may be a block copolymer or a random copolymer.

The molecular weight of the specific polymer is not particularly limited, and the weight average molecular weight measured by gel permeation chromatography (hereinafter, sometimes abbreviated as GPC) is preferably 1,500 to 100,000 and more preferably 2,000 to 50,000.

### <<Method for Producing Specific Polymer>>

The method for producing the specific polymer is not particularly limited, and for example, the specific polymer of the present embodiment can be obtained by causing a reaction of a carbon-carbon double bond of a monomer that provides the unit structure (A), a carbon-carbon double bond of a monomer that provides the unit structure (B), and a carbon-carbon double bond of a monomer that provides an arbitrary unit structure (C).

As a polymerization method for the specific polymer, a known polymerization method such as radical polymerization, anionic polymerization, or cationic polymerization can be used. Various known techniques such as solution polymerization, suspension polymerization, emulsion polymerization, and bulk polymerization can be used.

The polymerization initiator used in the polymerization is not particularly limited, and examples thereof include 2,2′-azobis(isobutyronitrile), 2,2′-azobis(2-methylbutyronitrile), 2,2′-azobis(2,4-dimethylvaleronitrile), 4,4′-azobis(4-cyanovaleric acid), 2,2′-azobis(2,4-dimethylvaleronitrile), 2,2′-azobis(4-methoxy-2,4-dimethylvaleronitrile), 2,2′-azobis(isobutyronitrile), 1,1′-azobis(cyclohexane-1-carbonitrile), 1-[(1-cyano-1-methylethyl)azo]formamide, 2,2′-azobis[2-(2-imidazolin-2-yl)propane]dihydrochloride, 2,2′-azobis[2-(2-imidazolin-2-yl)propane], and 2,2′-azobis(2-methylpropionamidine)dihydrochloride.

The solvent used in the polymerization is not particularly limited, and for example, dioxane, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, or the like can be used. These solvents may be used alone or in admixture.

The reaction temperature is not particularly limited, and is, for example, 20° C. to 150° C.

The reaction time is not particularly limited, and is, for example, 1 hour to 72 hours.

A solution containing the obtained polymer can also be used as it is for the preparation of the underlayer film-forming composition. The polymer can also be used by being isolated by precipitation in a poor solvent such as methanol, ethanol, isopropanol, or water, or a mixed solvent thereof and recovered.

The content of the specific polymer in the underlayer film-forming composition is not particularly limited, and is preferably 0.1 mass % to 50 mass %, and more preferably 0.1 mass % to 10 mass % with respect to the entire underlayer film-forming composition from the viewpoint of solubility.

Further, the content of the specific polymer in the underlayer film-forming composition is preferably 50 mass % to 95 mass %, more preferably 55 mass % to 90 mass %, and particularly preferably 60 mass % to 85 mass % with respect to the film constituent components.

The film constituent components mean components other than the solvent contained in the composition.

### <Crosslinking Agent>

The underlayer film-forming composition contains a crosslinking agent.

The crosslinking agent has a functional group that can react with the reactive group of the unit structure (B).

The number of functional groups in the crosslinking agent is not particularly limited, and may be one or two or more.

The functional group that can react with the reactive group of the unit structure (B) is not particularly limited, and examples thereof include a hydroxy group, an epoxy group, an acyl group, an acetyl group, a formyl group, a benzoyl group, a carboxy group, a carbonyl group, an amino group, an imino group, a cyano group, an azo group, an azide group, a thiol group, a sulfo group, an allyl group, and a structure represented by formula (D) below.

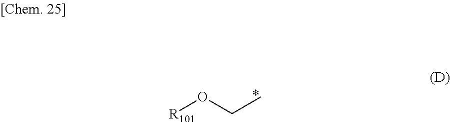

In formula (D), R₁₀₁ represents a hydrogen atom, an alkyl group having 1 to 4 carbon atoms, or an alkoxyalkyl group having 2 to 6 carbon atoms, and * represents a bond.

The bond is bonded to, for example, a nitrogen atom, a carbon atom included in an aromatic hydrocarbon ring, or the like.

When the reactive group of the unit structure (B) is a hydroxy group or a thiol group, examples of the functional group that can react with the reactive group of the unit structure (B) include a structure represented by formula (D).

When the reactive group of the unit structure (B) is an epoxy group, examples of the functional group that can react with the reactive group of the unit structure (B) include a carboxy group, an amino group, and a thiol group.

Examples of the crosslinking agent include a compound having two or more structures represented by formula (D).

As R₁₀₁, a hydrogen atom, a methyl group, an ethyl group, or a group represented by the following structure is preferable.

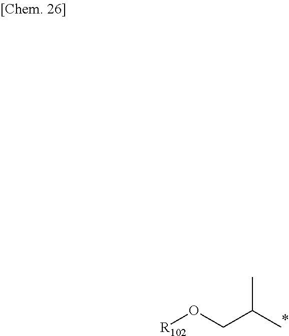

In the structure, R₁₀₂ represents a hydrogen atom, a methyl group, or an ethyl group, and * represents a bond.

The crosslinking agent is preferably a melamine compound, a guanamine compound, a glycoluril compound, a urea compound, or a compound having a phenolic hydroxy group. One type of these can be used alone or two or more types thereof can be used in combination.

The melamine compound is not particularly limited as long as it is a melamine compound having a group that can react with the reactive group (for example, a hydroxy group) of the unit structure (B).

Examples of the melamine compound include hexamethylolmelamine, hexamethoxymethylmelamine, a compound in which 1 to 6 methylol groups of hexamethylolmelamine are methoxymethylated or a mixture thereof, hexamethoxyethylmelamine, hexaacyloxymethylmelamine, and a compound in which 1 to 6 methylol groups of hexamethylolmelamine are acyloxymethylated or a mixture thereof.

The guanamine compound is not particularly limited as long as it is a guanamine compound having a group that can react with the reactive group (for example, a hydroxy group) of the unit structure (B).

Examples of the guanamine compound include tetramethylolguanamine, tetramethoxymethylguanamine, a compound in which 1 to 4 methylol groups of tetramethylolguanamine are methoxymethylated or a mixture thereof, tetramethoxyethylguanamine, tetraacyloxyguanamine, and a compound in which 1 to 4 methylol groups of tetramethylolguanamine are acyloxymethylated or a mixture thereof.

The glycoluril compound is not particularly limited as long as it is a glycoluril compound having a group that can react with the reactive group (for example, a hydroxy group) of the unit structure (B).

Examples of the glycoluril compound include tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof.

The glycoluril compound may be, for example, a glycoluril derivative represented by formula (1E) below.

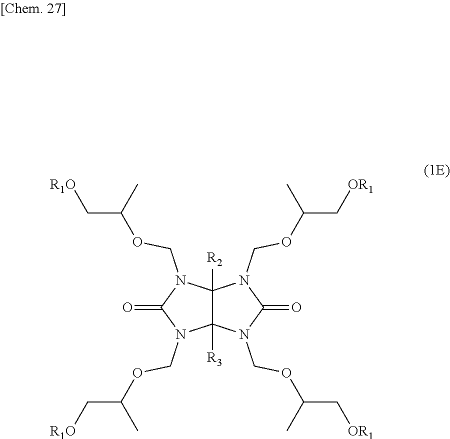

In formula (1E), four R₁'s each independently represent a methyl group or an ethyl group, and R₂ and R₃ each independently represent a hydrogen atom, an alkyl group having 1 to 4 carbon atoms, or a phenyl group.

Examples of the glycoluril derivative represented by formula (1E) include compounds represented by formulae (1E-1) to (1E-6) below.

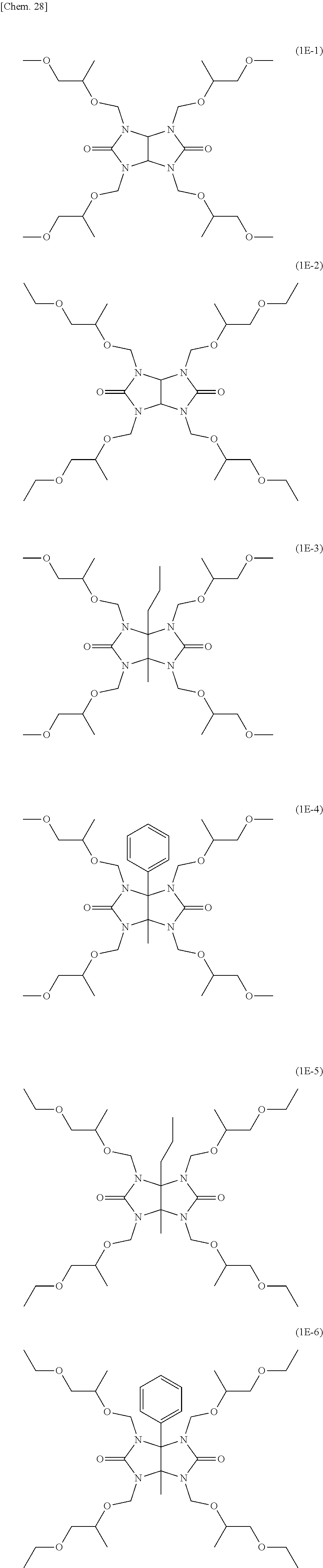

The glycoluril derivative represented by formula (1E) is obtained by, for example, allowing a glycoluril derivative represented by formula (2E) below to react with at least one type of compound represented by formula (3d) below.

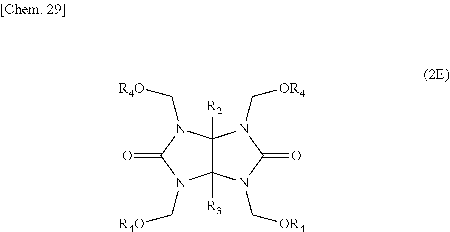

In formula (2E), R₂ and R₃ each independently represent a hydrogen atom, an alkyl group having 1 to 4 carbon atoms, or a phenyl group, and R₄'s each independently represent an alkyl group having 1 to 4 carbon atoms.

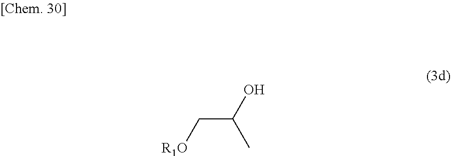

In formula (3d), R₁ represents a methyl group or an ethyl group.

Examples of the glycoluril derivative represented by formula (2E) include compounds represented by formulae (2E-1) to (2E-4) below. Examples of the compound represented by formula (3d) include compounds represented by formula (3d-1) and formula (3d-2) below.

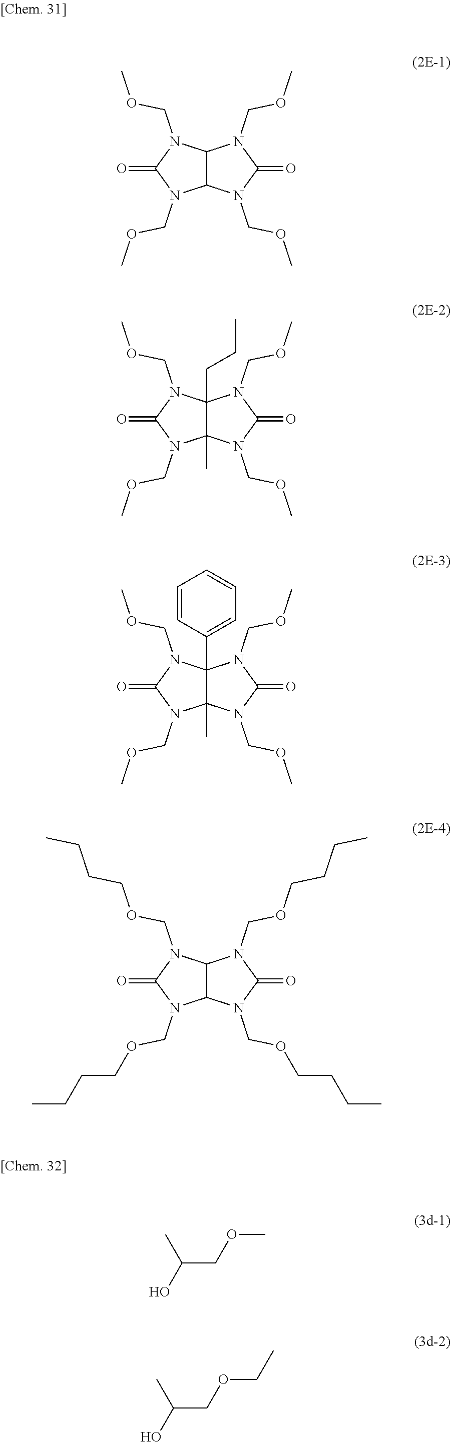

The urea compound is not particularly limited as long as it is a urea compound having a group that can react with the reactive group (for example, a hydroxy group) of the unit structure (B).

Examples of the urea compound include tetramethylol urea, tetramethoxy methyl urea, a compound in which 1 to 4 methylol groups of tetramethylol urea are methoxymethylated or a mixture thereof, and tetramethoxy ethyl urea.

Examples of the compound having a phenolic hydroxy group include compounds represented by formula (111) or formula (112) below.

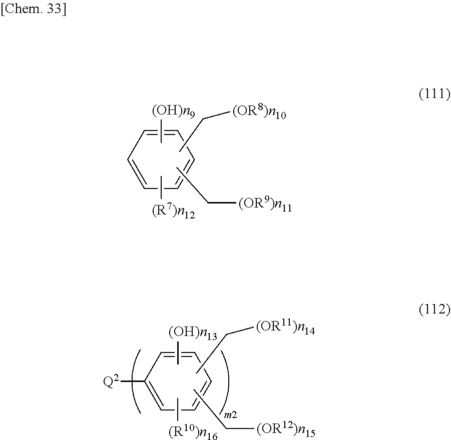

In formula (111) and formula (112), Q² represents a single bond or an m2-valent organic group,
R⁸, R⁹, R¹¹, and R¹² each represent a hydrogen atom or a methyl group,
R⁷ and R¹⁰ each represent an alkyl group having 1 to 10 carbon atoms or an aryl group having 6 to 40 carbon atoms,
n₉ represents an integer that meets 1≤n₉≤3, n₁₀ represents an integer that meets 2≤n₁₀≤5, n₁₁ represents an integer that meets 0≤n₁₁≤3, and n₁₂ represents an integer that meets 0≤n₁₂≤3, and an integer that meets 3≤(n₉+n₁₀+n₁₁+n₁₂)≤6,
n₁₃ represents an integer that meets 1≤n₁₃≤3, n₁₄ represents an integer that meets 1≤n₁₄≤4, n₁₅ represents an integer that meets 0≤n₁₅≤3, and n₁₆ represents an integer that meets 0≤n₁₆≤3, and an integer that meets 2≤(n₁₃+n₁₄+n₁₅+n₁₆)≤5, and
m2 represents an integer of 2 to 10.

Examples of the m2-valent organic group in Q² include an m2-valent organic group having 1 to 4 carbon atoms.

Examples of the compound represented by formula (111) or formula (112) include the following compounds.

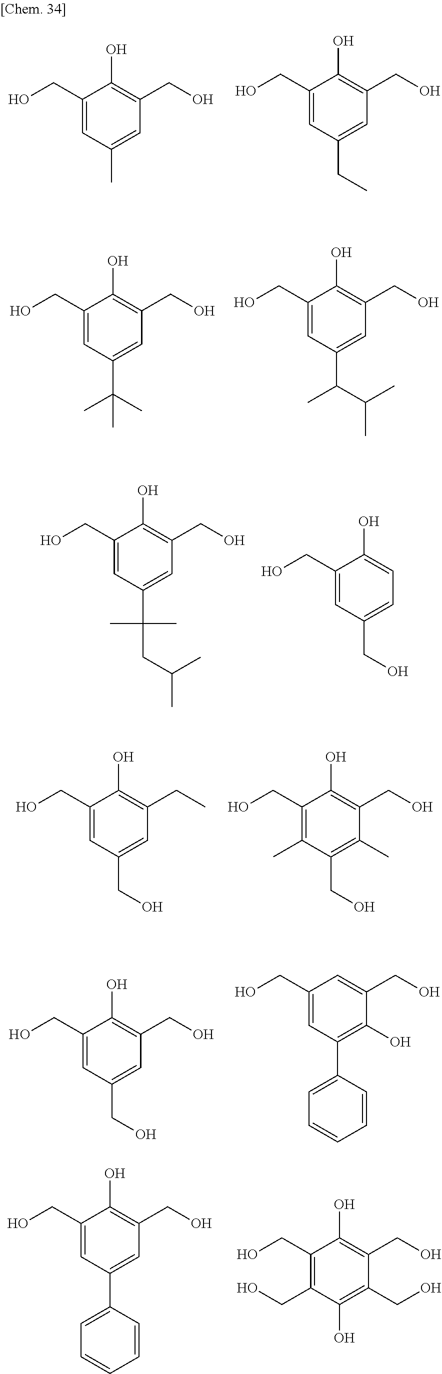

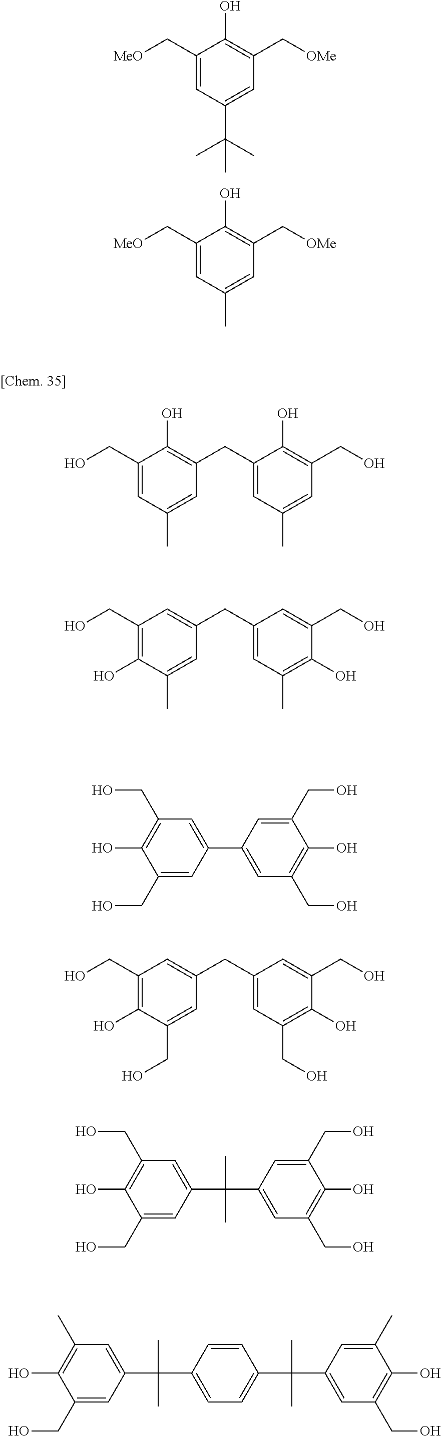

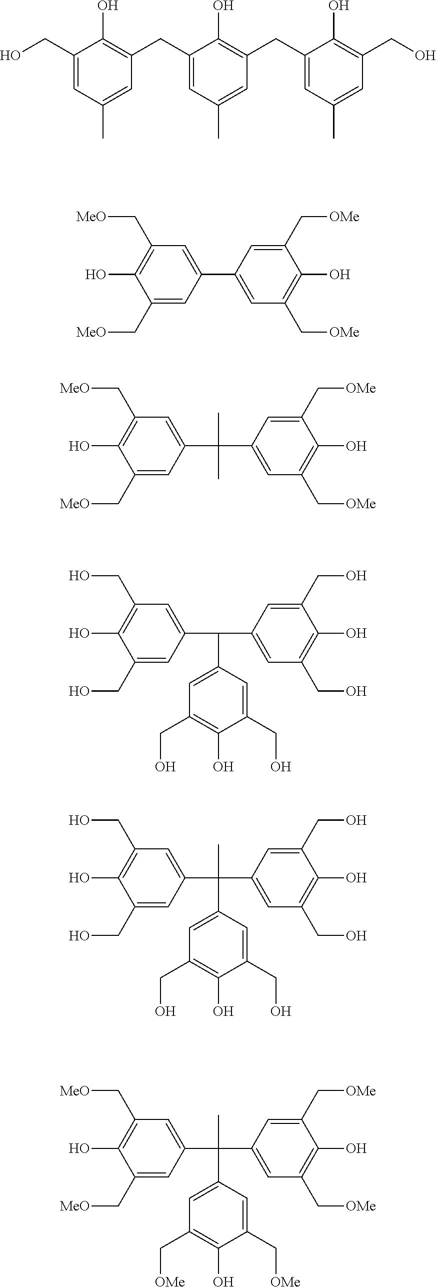 [SMILES: Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The compounds are available as products of Asahi Organic Chemicals Industry Co., Ltd. and Honshu Chemical Industry Co., Ltd. Examples of the products include TMOM-BP (trade name) manufactured by Asahi Organic Chemicals Industry Co., Ltd.

Among the compounds, the glycoluril compound is preferable. Specifically, tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof are preferable, and tetramethoxymethylglycoluril is preferable.

The molecular weight of the crosslinking agent is not particularly limited, and is preferably 500 or less.

The content of the crosslinking agent in the underlayer film-forming composition is not particularly limited, and is preferably 5 mass % to 60 mass %, more preferably 10 mass % to 55 mass %, and particularly preferably 20 mass % to 50 mass % of the specific polymer.

### <Curing Catalyst>

As the curing catalyst contained as an optional component in the underlayer film-forming composition, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium p-toluenesulfonate (pyridinium p-toluenesulfonic acid), pyridinium phenolsulfonate, pyridinium p-hydroxybenzenesulfonate (p-phenolsulfonic acid pyridinium salt), pyridinium trifluoromethanesulfonate, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, hydroxybenzoic acid, N-methylmorpholine-p-toluenesulfonic acid, N-methylmorpholine-p-hydroxybenzenesulfonic acid, and N-methylmorpholine-5-sulfosalicylic acid.

Examples of the photoacid generator include onium salt compounds, sulfonimide compounds, and disulfonyldiazomethane compounds.

Examples of the onium salt compounds include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compounds include N-(trifluoromethanesulfonyloxy) succinimide, N-(nonafluoronormalbutanesulfonyloxy) succinimide, N-(camphorsulfonyloxy) succinimide, and N-(trifluoromethanesulfonyloxy) naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

Only one type of curing catalyst can be used, or two or more types thereof can be used in combination.

In the case of using the curing catalyst, the content ratio of the curing catalyst is, for example, 0.1 mass % to 50 mass %, and preferably 1 mass % to 30 mass % with respect to the crosslinking agent.

### <Another Component>

To the underlayer film-forming composition, a surfactant can be further added in order to further improve the coatability for surface unevenness without generating a pinhole, a striation, and the like.

Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (trade name, manufactured by Tochem Products Co., Ltd.), MEGAFAC F171, F173, and R-30 (trade name, manufactured by DIC Corporation), Fluorad FC430 and FC431 (trade name, manufactured by Sumitomo 3M Limited), Asahi Guard AG710, Surflon S-382, SC101, SC102, SC103, SC104, SC105, and SC106 (trade name, manufactured by AGC Corporation), and an organosiloxane polymer KP341 (manufactured by Shin-Etsu Chemical Co., Ltd.).

The blending amount of these surfactants is not particularly limited, and is usually 2.0 mass % or less, and preferably 1.0 mass % or less with respect to the underlayer film-forming composition.

These surfactants may be added alone, or two or more types thereof can also be added in combination.

### <Solvent>

The underlayer film-forming composition may contain a solvent.

As the solvent, an organic solvent generally used in a chemical liquid for a semiconductor lithography process is preferable. Specific examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used alone or two or more types thereof can be used in combination.

Among these solvents, propylene glycol monomethyl ether, propylene glycol monomethyl ether acetate, ethyl lactate, butyl lactate, and cyclohexanone are preferable. Propylene glycol monomethyl ether and propylene glycol monomethyl ether acetate are particularly preferable.

The content of the solvent in the underlayer film-forming composition is not particularly limited, and is preferably 80 mass % to 99.99 mass %, more preferably 90 mass % to 99.95 mass %, and particularly preferably 95 mass % to 99.9 mass %.

### (Underlayer Film)

The underlayer film of the present invention is a baked product of a coating film of the underlayer film-forming composition.

The underlayer film of the present invention is used, in lithography using a resist film of either a photoresist film or an electron beam resist film and a self-assembled film, as an underlayer film of the resist film, and then further used as an underlayer film of the self-assembled film.

The underlayer film of the present invention can be produced by applying the underlayer film-forming composition onto a semiconductor substrate and baking the composition.

Examples of the semiconductor substrate to which the underlayer film-forming composition of the present invention is applied include silicon wafers, germanium wafers, and compound semiconductor wafers such as gallium arsenide, indium phosphide, gallium nitride, indium nitride, and aluminum nitride.

In the case of using a semiconductor substrate having a surface on which an inorganic film is formed, the inorganic film is formed with, for example, an atomic layer deposition (ALD) method, a chemical vapor deposition (CVD) method, a reactive sputtering method, an ion plating method, a vacuum deposition method, or a spin coating method (spin-on-glass: SOG). Examples of the inorganic film include a polysilicon film, a silicon oxide film, a silicon nitride film, a boro-phospho silicate glass (BPSG) film, a titanium nitride film, a titanium oxynitride film, a tungsten film, a gallium nitride film, and a gallium arsenide film.

The semiconductor substrate may have a silicon and organic group-containing film. The silicon and organic group-containing film is a film formed using a hydrolysis condensate of a hydrolyzable silane having an organic group (also referred to as an organosilicon compound). The silicon and organic group-containing film contains, for example, a hydrolysis condensate of a hydrolyzable silane containing a compound represented by formula (A) below.

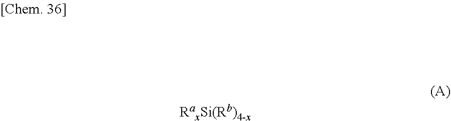

In formula (A), R^{a} represents an alkyl group, an aryl group, a halogenated alkyl group, a halogenated aryl group, an alkoxyaryl group, an alkenyl group, an organic group having an epoxy group, an organic group having an acryloyl group, an organic group having a methacryloyl group, an organic group having a mercapto group, or an organic group having a cyano group, R^{b} represents an alkoxy group, an acyloxy group, or a halogen atom, and x represents an integer of 0 to 3.

The silicon and organic group-containing film can be formed of, for example, a silicon-containing resist underlayer film-forming composition. Examples of such a silicon-containing resist underlayer film-forming composition include silicon-containing resist underlayer film-forming compositions described below.

JP 2020-076999 A, WO 2019/181873 A, WO 2019/082934 A, WO 2019/009413 A, WO 2018/181989 A, WO 2018/079599 A, WO 2016/080217 A, WO 2016/009965 A, WO 2016/009939 A, WO 2015/194555 A, WO 2014/098076 A, WO 2014/069329 A, WO 2014/046055 A, WO 2013/191203 A, WO 2013/115032 A, WO 2013/022099 A, WO 2012/102261 A, WO 2012/053600 A, WO 2012/039337 A, WO 2011/105368 A, WO 2011/102470 A, WO 2011/033965 A, WO 2010/140551 A, WO 2010/071155 A, WO 2010/021290 A, WO 2009/104552 A, WO 2009/088039 A, WO 2009/069712 A

The resist underlayer film-forming composition of the present invention is applied onto such a semiconductor substrate with an appropriate application method using a spinner, a coater, or the like. Then, the composition is baked using a heating unit such as a hot plate to form a resist underlayer film. The baking conditions are appropriately selected from a baking temperature of 100° C. to 400° C. and a baking time of 0.3 minutes to 60 minutes. It is preferable that the baking temperature is 120° C. to 350° C. and the baking time is 0.5 minutes to 30 minutes, and it is more preferable that the baking temperature is 150° C. to 300° C. and the baking time is 0.8 minutes to 10 minutes.

The film thickness of the underlayer film is preferably less than 10 nm, more preferably 9 nm or less, still more preferably 8 nm or less, and particularly preferably 7 nm or less from the viewpoint of suitably obtaining the effect of the present invention. The film thickness of the underlayer film may be 1 nm or more, 2 nm or more, or 3 nm or more.

Usually, when the film thickness of the resist underlayer film is reduced, it is difficult to obtain a film having a flat surface. When the surface is not flat, the variation in the film thickness of the resist film to be formed on the underlayer film increases, resulting in an increase in the roughness of the resist pattern.

When the underlayer film-forming composition of the present invention contains the above-described polymer, an underlayer film excellent in adhesion to a substrate and film formability tends to be obtained. Therefore, it is presumed that even when the film thickness of the underlayer film is less than 10 nm, a film having a flat surface can be formed, and thus the roughness (LWR or CDU) of the resist pattern can be improved. The LWR (Line width roughness) is mainly evaluated based on the line and space (wiring pattern) of the resist pattern, but the underlayer film of the present application is also effective in improving CDU (Critical Dimendion Uniformity, CD Uniformity) (less variation in hole diameter) when the resist pattern is a contact hole (hole pattern).

The CDU can be evaluated, for example, by a method according to the method described in JP 2020-003678 A (evaluation of in-plane uniformity (CDU) of pattern dimensions in paragraph [0386]).

Further, when a brush layer is formed in a gap of a pattern of the patterned underlayer film, the brush layer becomes a thin layer (for example, about 1 nm). From the viewpoint of reducing the difference from the film thickness of the brush layer, it is preferable to reduce the film thickness of the underlayer film. In this respect, the film thickness of the underlayer film is preferably less than 10 nm.

In addition, by reducing the film thickness of the underlayer film, the pattern of the patterned self-assembled film is easily transferred when being transferred to the underlayer film. In this respect, the thickness of the underlayer film is preferably less than 10 nm.

The method for measuring the film thickness of the resist underlayer film in the present description is as follows.
Measurement apparatus name: Ellipsometric Film Thickness Measurement System RE-3100 (SCREEN Semiconductor Solutions Co., Ltd.)
Single wavelength ellipsometer (SWE) mode
Arithmetic average of eight points (for example, eight points are measured at intervals of 1 cm in the X direction of the wafer.)

### (Method for Producing Semiconductor Element)

The method for producing a semiconductor element of the present invention includes first to fifth steps.
First step: a step of forming an underlayer film on a semiconductor substrate using the underlayer film-forming composition of the present invention
Second step: a step of forming a resist film of either a photoresist film or an electron beam resist film on the underlayer film
Third step: a step of obtaining a resist pattern by irradiating the resist film with light or an electron beam, and then developing the resist film
Fourth step: a step of etching the underlayer film using a resist pattern as a mask to form a patterned underlayer film
Fifth step: a step of forming a self-assembled film on the patterned underlayer film

The method for producing a semiconductor element of the present invention may further include a sixth step.
Sixth step: a step of forming a brush layer in a gap of a pattern of the patterned underlayer film

The sixth step is a step performed between the fourth step and the fifth step.

### <First Step>

The first step is a step of forming an underlayer film on a semiconductor substrate using the underlayer film-forming composition of the present invention. The method for forming the underlayer film is not particularly limited, and examples thereof include the above-described method. That is, the underlayer film can be produced by applying the underlayer film-forming composition onto a semiconductor substrate and baking the composition.

The film thickness of the underlayer film is preferably less than 10 nm, more preferably 9 nm or less, still more preferably 8 nm or less, and particularly preferably 7 nm or less from the viewpoint of suitably obtaining the effect of the present invention. The film thickness of the underlayer film may be 1 nm or more, 2 nm or more, or 3 nm or more.

### <Second Step, Third Step, and Fourth Step>

The second step is a step of forming a resist film of either a photoresist film or an electron beam resist film on the underlayer film.

The third step is a step of obtaining a resist pattern by irradiating the resist film with light or an electron beam, and then developing the resist film.

The fourth step is a step of etching the underlayer film using a resist pattern as a mask to form a patterned underlayer film.

The film thickness of the resist film to be formed is not particularly limited, and is preferably 200 nm or less, more preferably 150 nm or less, still more preferably 100 nm or less, and particularly preferably 80 nm or less. The film thickness of the resist film is preferably 10 nm or more, more preferably 20 nm or more, and still more preferably 30 nm or more.

A resist formed on the underlayer film by application and baking using a known method is not particularly limited as long as the resist responds to light or an electron beam (EB) used for irradiation. Both a negative photoresist and a positive photoresist can be used.

In the present description, a resist that responds to an EB is also sometimes referred to as a photoresist.

Examples of the photoresist include a positive photoresist made of a novolac resin and 1,2-naphthoquinonediazide sulfonic acid ester, a chemically amplified photoresist made of a binder having a group, which is decomposed by an acid to increase the alkali dissolution rate, and a photoacid generator, a chemically amplified photoresist made of a low molecular compound, which is decomposed by an acid to increase the alkali dissolution rate of the photoresist, an alkali-soluble binder, and a photoacid generator, a chemically amplified photoresist made of a binder having a group, which is decomposed by an acid to increase the alkali dissolution rate, a low molecular compound, which is decomposed by an acid to increase the alkali dissolution rate of the photoresist, and a photoacid generator, and a resist containing a metal element. Examples thereof include V146G (trade name) manufactured by JSR Corporation, APEX-E (trade name) manufactured by Shipley, PAR710 (trade name) manufactured by SUMITOMO CHEMICAL COMPANY, LIMITED, and AR2772 and SEPR430 (trade names) manufactured by Shin-Etsu Chemical Co., Ltd. Further, examples thereof include fluorine atom-containing polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

Further, a resist composition, a radiation-sensitive resin composition, a so-called resist composition such as a high-resolution patterning composition based on an organometallic solution, and a metal-containing resist composition described in the following documents can be used, but not limited thereto: WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, and JP 2011-253185 A.

Examples of the resist composition include the following compositions.

An active ray-sensitive or radiation-sensitive resin composition that contains a resin A including a repeating unit having an acid decomposable group in which a polar group is protected by a protecting group to be removed by the action of an acid, and that contains a compound represented by general formula (21) below.

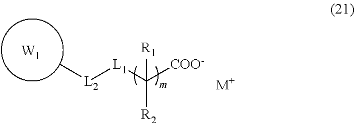

In general formula (21), m represents an integer of 1 to 6,
R₁ and R₂ each independently represent a fluorine atom or a perfluoroalkyl group,
L₁ represents —O—, —S—, —COO—, —SO₂—, or —SO₃—,
L₂ represents an alkylene group which may have a substituent, or a single bond,
W₁ represents a cyclic organic group which may have a substituent, and
M⁺ represents a cation.

A metal-containing film-forming composition for extreme ultraviolet or electron lithography, containing a compound having a metal-oxygen covalent bond and a solvent, in which metal elements included in the compound belong to periods 3 to 7 of groups 3 to 15 in the periodic table.

A radiation-sensitive resin composition that contains a polymer having a first structural unit represented by formula (31) below and a second structural unit represented by formula (32) below and containing an acid-dissociable group, and that contains an acid generator.

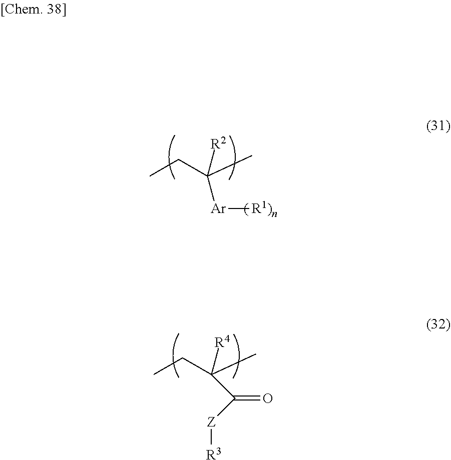

In formula (31), Ar is a group obtained by removing (n+1) hydrogen atoms from an arene having 6 to 20 carbon atoms, R¹ is a hydroxy group, a sulfanyl group, or a monovalent organic group having 1 to 20 carbon atoms, n is an integer of 0 to 11, when n is 2 or more, a plurality of R¹'s are identical or different, and R² is a hydrogen atom, a fluorine atom, a methyl group, or a trifluoromethyl group. In formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group.

A resist composition that contains a resin (A1) including a structural unit having a cyclic carbonate structure, a structural unit represented by the following formula, and a structural unit having an acid-unstable group, and that contains an acid generator.

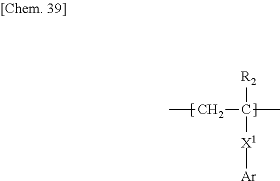

In the formula,
R² represents an alkyl group which has 1 to 6 carbon atoms and may have a halogen atom or represents a hydrogen atom or a halogen atom, X¹ represents a single bond, —CO—O—*, or —CO—NR⁴—*, * represents a bond with —Ar, R⁴ represents a hydrogen atom or an alkyl group having 1 to 4 carbon atoms, and Ar represents an aromatic hydrocarbon group which has 6 to 20 carbon atoms and may have one or more groups selected from the group consisting of a hydroxy group and a carboxyl group.

Examples of the resist film include the following resist film.

A resist film including a base resin including a repeating unit represented by formula (a1) below and/or a repeating unit represented by formula (a2) below, and a repeating unit that generates an acid bonded to a polymer main chain by exposure.

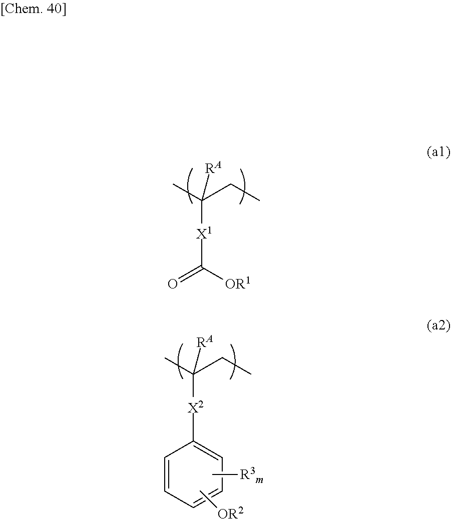

In formula (a1) and formula (a2), R^{A}'s are each independently a hydrogen atom or a methyl group, R¹ and R² are each independently a tertiary alkyl group having 4 to 6 carbon atoms, R³'s are each independently a fluorine atom or a methyl group, m is an integer of 0 to 4, X¹ is a single bond, a phenylene group, a naphthylene group, or a linking group having 1 to 12 carbon atoms and including at least one type selected from an ester bond, a lactone ring, a phenylene group, and a naphthylene group, and X² is a single bond, an ester bond, or an amide bond.

Examples of the resist material include the following resist material.

A resist material containing a polymer having a repeating unit represented by formula (b1) or formula (b2) below.

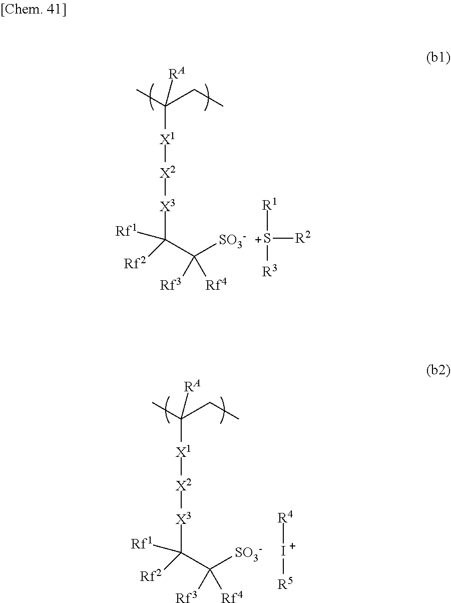

In formula (b1) and formula (b2), R^{A} is a hydrogen atom or a methyl group, X¹ is a single bond or an ester group, X² is a linear, branched, or cyclic alkylene group having 1 to 12 carbon atoms or an arylene group having 6 to 10 carbon atoms, and a part of a methylene group included in the alkylene group may be substituted with an ether group, an ester group, or a lactone ring-containing group, and at least one hydrogen atom included in X² is substituted with a bromine atom, X³ is a single bond, an ether group, an ester group, or a linear, branched, or cyclic alkylene group having 1 to 12 carbon atoms, and a part of a methylene group included in the alkylene group may be substituted with an ether group or an ester group, Rf¹ to Rf⁴ are each independently a hydrogen atom, a fluorine atom, or a trifluoromethyl group, and at least one of Rf¹ to Rf⁴ is a fluorine atom or a trifluoromethyl group, alternatively, Rf¹ and Rf² may be combined to form a carbonyl group, R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and some of methylene groups included in these groups may be substituted with an ether group, an ester group, a carbonyl group, a carbonate group, or a sulfonic acid ester group, and R¹ and R² may be bonded to form a ring together with a sulfur atom to which R¹ and R² are bonded.

A resist material containing a base resin including a polymer having a repeating unit represented by formula (a) below.

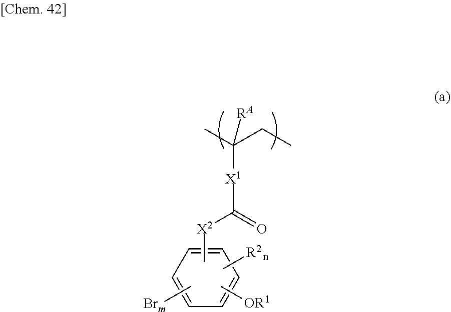

In formula (a), R^{A} is a hydrogen atom or a methyl group, R¹ is a hydrogen atom or an acid-unstable group, R² is a linear, branched, or cyclic alkyl group having 1 to 6 carbon atoms or a halogen atom other than bromine, X¹ is a single bond, a phenylene group, or a linear, branched, or cyclic alkylene group which has 1 to 12 carbon atoms and may include an ester group or a lactone ring, X² is —O—, —O—CH₂—, or —NH—, m is an integer of 1 to 4, u is an integer of 0 to 3, provided that m+u is an integer of 1 to 4.

A resist composition which generates an acid by exposure and whose solubility in a developer is changed by an action of an acid, the resist composition containing:
a base material component (A) whose solubility in a developer is changed by an action of an acid; and a fluorine additive component (F) which exhibits decomposability in an alkaline developer,
wherein the fluorine additive component (F) contains a fluororesin component (F1) having a structural unit (f1) containing a base-dissociable group and a structural unit (f2) containing a group represented by general formula (f2-r-1) below.

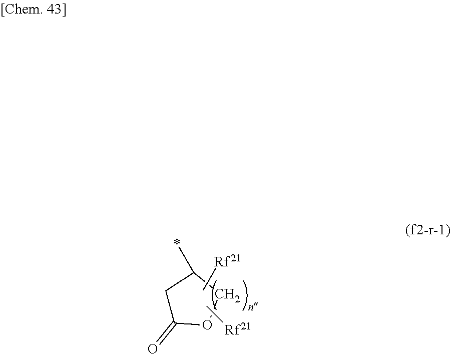

In formula (f2-r-1), Rf²¹'s are each independently a hydrogen atom, an alkyl group, an alkoxy group, a hydroxy group, a hydroxyalkyl group, or a cyano group, n″ is an integer of 0 to 2, and * is a bond.

The structural unit (f1) includes a structural unit represented by general formula (f1-1) below or a structural unit represented by general formula (f1-2) below.

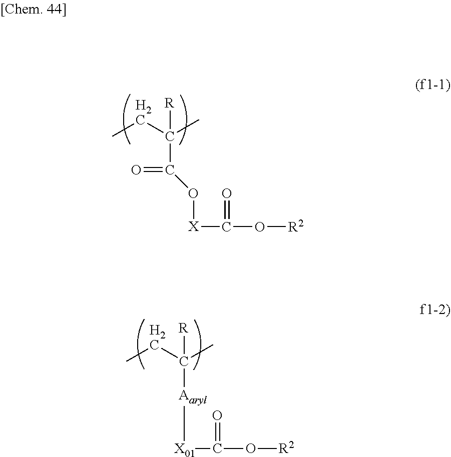

In formulae (f1-1) and (f1-2), R's are each independently a hydrogen atom, an alkyl group having 1 to 5 carbon atoms, or a halogenated alkyl group having 1 to 5 carbon atoms, X is a divalent linking group not having an acid-dissociable site, A_{aryl} is a divalent aromatic cyclic group which may have a substituent, X₀₁ is a single bond or a divalent linking group, and R²'s are each independently an organic group having a fluorine atom.

Examples of a coating, a coating solution, and a coating composition include the followings.

A coating including a metal oxo-hydroxo network having organic ligands via a metal carbon bond and/or a metal carboxylate bond.

An inorganic oxo/hydroxo-based composition.

A coating solution containing: an organic solvent; a first organometallic composition represented by the formula R_{z}SnO_{(2-(z/2)-(x/2}))(OH)ₓ (where 0<z≤2 and 0<(z+x)≤4), the formula R′ₙSnX₄₋ₙ (where n=1 or 2), or a mixture thereof, wherein R and R′ are independently a hydrocarbyl group having 1 to 31 carbon atoms, and X is a ligand having a hydrolysable bond to Sn or a combination thereof; and a hydrolyzable metal compound represented by the formula MX′ᵥ (wherein M is a metal selected from groups 2 to 16 in the element periodic table, “v” is a number satisfying v=2 to 6, and X′ is a ligand having a hydrolysable M-X bond or a combination thereof).

A coating solution containing an organic solvent, and a first organometallic compound represented by the formula RSnO_{(3/2-x/2)}(OH)ₓ (where 0<x<3), wherein the solution contains about 0.0025 M to about 1.5 M of tin, R is an alkyl group or a cycloalkyl group having 3 to 31 carbon atoms, and the alkyl group or the cycloalkyl group is bonded to tin via a secondary or tertiary carbon atom.

An aqueous inorganic pattern forming precursor solution containing a mixture of water, metal suboxide cations, polyatomic inorganic anions, and radiation-sensitive ligands having a peroxide group.

Irradiation with light or an electron beam is performed, for example, through a mask (reticle) for formation of a predetermined pattern. The wavelength of the light is not particularly limited. The underlayer film of the present invention is suitably applied for irradiation with an electron beam (EB) or an extreme ultraviolet ray (EUV) (13.5 nm), but is more preferably applied for extreme ultraviolet (EUV) exposure.

The irradiation energy of EB and the exposure amount of EUV are not particularly limited.

Post exposure bake (PEB) may be performed after irradiation with light or an electron beam and before development.

The baking temperature is not particularly limited, and is preferably 60° C. to 150° C., more preferably 70° C. to 120° C., and particularly preferably 75° C. to 110° C.

The baking time is not particularly limited, and is preferably 1 second to 10 minutes, more preferably 10 seconds to 5 minutes, and particularly preferably 30 seconds to 3 minutes.

For the development, for example, an alkaline developer is used.

The developing temperature is, for example, 5° C. to 50° C.

The developing time is, for example, 10 seconds to 300 seconds.

As the alkaline developer, for example, an aqueous solution of an alkali such as an inorganic alkali such as sodium hydroxide, potassium hydroxide, sodium carbonate, sodium silicate, sodium metasilicate, or ammonia water, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide, tetraethylammonium hydroxide, or choline, or a cyclic amine such as pyrrole or piperidine can be used. Further, an alcohol such as isopropyl alcohol, or a surfactant such as a nonionic surfactant can be added in an appropriate amount to the aqueous solution of an alkali and used. Among these developers, an aqueous solution of a quaternary ammonium salt is preferable, and an aqueous solution of tetramethylammonium hydroxide and an aqueous solution of choline are more preferable. Further, a surfactant or the like can also be added to these developers. In place of the alkaline developer, it is also possible to use a method for performing development with an organic solvent such as butyl acetate and developing a portion where the alkaline dissolution rate of photoresist is not improved.

The type of the resist pattern to be formed is not particularly limited, and may be a line pattern or a hole pattern.

The line width when the resist pattern is a line pattern is not particularly limited, and is, for example, 30 nm to 200 nm.

When the resist pattern is a hole pattern, the diameter of the hole is, for example, 30 nm to 200 nm.

Subsequently, the underlayer film is etched using the formed resist pattern as a mask. The etching may be dry etching or wet etching, and dry etching is preferable.

After the fourth step, a step of removing the resist pattern may be included.

The resist pattern is removed by, for example, etching. The etching may be dry etching or wet etching.

The resist pattern is usually removed before the fifth step.

### <Fifth Step>

The fifth step is a step of forming a self-assembled film on the patterned underlayer film.

The self-assembled film can be formed, for example, by applying a self-assembled film-forming composition and drying the composition.

The self-assembled film is, for example, a film containing a block copolymer.

The film thickness of the self-assembled film is not particularly limited, and is preferably 10 nm to 100 nm, more preferably 30 nm to 80 nm, and particularly preferably 40 nm to 60 nm.

### <<Self-Assembled Film-Forming Composition>>

A self-assembled film-forming composition contains a block copolymer.

The self-assembled film-forming composition usually contains a solvent.

The self-assembled film-forming composition may have a solid content of 0.1 to 10 mass %, 0.1 to 5 mass %, or 0.1 to 3 mass %. The solid content is a remaining proportion obtained by removing the solvent from the film-forming composition.

A ratio of the block copolymer in the solid content can be 30 to 100 mass %, 50 to 100 mass %, 50 to 90 mass %, or 50 to 80 mass %.

The number of types of blocks present in the block copolymer can be 2 or 3 or more. The number of blocks present in the block copolymer can be 2 or 3 or more.

### <<<Block Copolymer>>>

Examples of the block polymer include combinations of AB, ABAB, ABA, and ABC.

As one of the methods for synthesizing the block copolymer, living radical polymerization and living cationic polymerization in which a polymerization process includes only an initiation reaction and a growth reaction and is not accompanied by a side reaction for deactivating a growth terminal can be used. The growth terminal can keep the growth active reaction during the polymerization reaction. By eliminating the occurrence of chain transfer, a polymer (PA) having a uniform length is obtained. By adding a different monomer (mb), the growth terminal of the polymer (PA) can be utilized to allow the polymerization of the monomer (mb) to proceed to form a block copolymer (AB).

For example, when there are two types of blocks PA and PB, a molar ratio of the polymer chain (PA) to the polymer chain (PB) can be 1:9 to 9:1 and preferably 3:7 to 7:3.

A volume ratio of the block copolymer is, for example, 30:70 to 70:30.

A homopolymer PA or PB is a polymer of a polymerizable compound having at least one radically polymerizable reactive group (vinyl group or vinyl group-containing organic group).

A weight average molecular weight Mw of the block copolymer is preferably 1,000 to 100,000 or 5,000 to 100,000. When the weight average molecular weight of the block copolymer is 1,000 or more, the applicability onto a base substrate is excellent, and when the weight average molecular weight of the block copolymer is 100,000 or less, the solubility in a solvent is excellent.

A polydispersity (Mw/Mn) of the block copolymer is preferably 1.00 to 1.50 and more preferably 1.00 to 1.20.

As the block copolymer used in the present invention, a known block copolymer can be used.

As a specific example of the block copolymer, a combination of a silicon-containing polymer chain and a non-silicon-containing polymer chain is preferable because a difference in dry etching rate can be increased.

Examples of the silicon-containing polymer chain include a silylated polystyrene derivative. Examples of the silylated polystyrene derivative include polysilanes (for example, polydihexylsilane and the like), polysiloxanes (for example, polydimethylsiloxane and the like), poly(trimethylsilylstyrene), and poly(pentamethyldisilylstyrene).

Particularly, the silylated polystyrene derivative is preferably poly(4-trimethylsilylstyrene) or poly(4-pentamethyldisilylstyrene) having a substituent at the 4-position.

A preferred example of the block copolymer is a block copolymer obtained by binding a silicon-free polymer having styrene as a structural unit which may be substituted with an organic group or a silicon-free polymer having a structure derived from lactide as a structural unit to a silicon-containing polymer having styrene substituted with a silicon-containing group as a structural unit.

Among them, a combination of a silylated polystyrene derivative and a polystyrene derivative, or a combination of a silylated polystyrene derivative and polylactide is preferable.

Among them, a combination of a silylated polystyrene derivative having a substituent at the 4-position and a polystyrene derivative having a substituent at the 4-position, or a combination of a silylated polystyrene derivative having a substituent at the 4-position and polylactide is preferable.

More preferred specific examples of the block copolymer include a combination of poly(trimethylsilylstyrene) and polymethoxystyrene, a combination of polystyrene and poly(trimethylsilylstyrene), and a combination of poly(trimethylsilylstyrene) and poly(D,L-lactide).

More preferred specific examples of the block copolymer include a combination of poly(4-trimethylsilylstyrene) and poly(4-methoxystyrene), a combination of polystyrene and poly(4-trimethylsilylstyrene), and a combination of poly(4-trimethylsilylstyrene) and poly(D,L-lactide).

Most preferred specific examples of the block copolymers include a poly(4-methoxystyrene)/poly(4-trimethylsilylstyrene) block copolymer and a polystyrene/poly(4-trimethylsilylstyrene) block copolymer.

The entire disclosure described in WO 2018/135456 A is incorporated herein by reference.

In addition, the block copolymer may be a block copolymer obtained by binding a silicon-free polymer to a silicon-containing polymer having styrene substituted with a silicon-containing group as a structural unit, and the silicon-free polymer may be a block copolymer having a unit structure represented by formula (1-1c) or formula (1-2c) below.

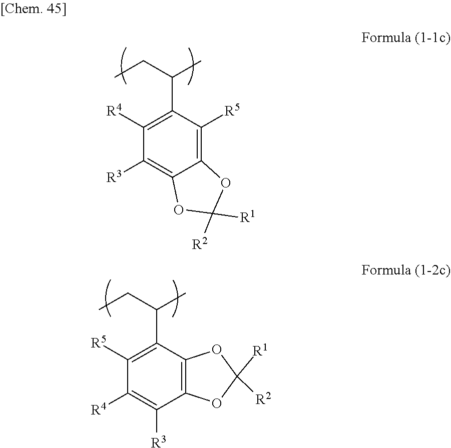

In formula (1-1c) or formula (1-2c), R and R² each independently represent a hydrogen atom, a halogen atom, or an alkyl group having 1 to 10 carbon atoms, and R³ to R⁵ each independently represent a hydrogen atom, a hydroxy group, a halogen atom, an alkyl group having 1 to 10 carbon atoms, an alkoxy group having 1 to 10 carbon atoms, a cyano group, an amino group, an amide group, or a carbonyl group.

The silicon-containing group may contain one silicon atom.

The silicon-containing polymer may have a unit structure represented by formula (2c) below.

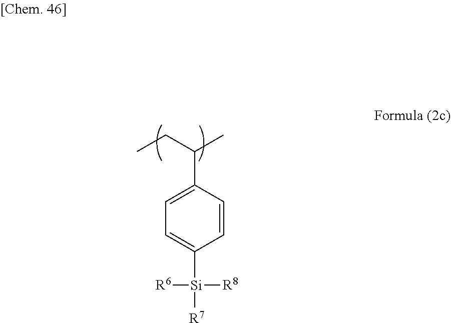

In formula (2c), R⁶ to R⁸ each independently represent an alkyl group having 1 to 10 carbon atoms or an aryl group having 6 to 40 carbon atoms.

Further, as the block copolymer, a block copolymer described in JP 2019-507815 A including the following
[BCP11] to [BCP14] may be used. The entire disclosure described in JP 2019-507815 A is incorporated herein by reference.
[BCP11] A block copolymer containing 5-vinylbenzo[d][1,3]dioxole.
[BCP12] The block copolymer according to [BCP11], in which the block copolymer further contains a block containing silicon.
[BCP13] The block copolymer according to [BCP12], in which the block copolymer further contains pentamethyldisilylstyrene.
[BCP14] The block copolymer according to [BCP13], in which the block copolymer is poly(5-vinylbenzo[d][1,3]dioxole)-b-poly(pentamethyldisilylstyrene).

The synthesis of poly(5-vinylbenzo[d][1,3]dioxole-block-4-pentamethyldisilylstyrene) as described above is shown in scheme 1.

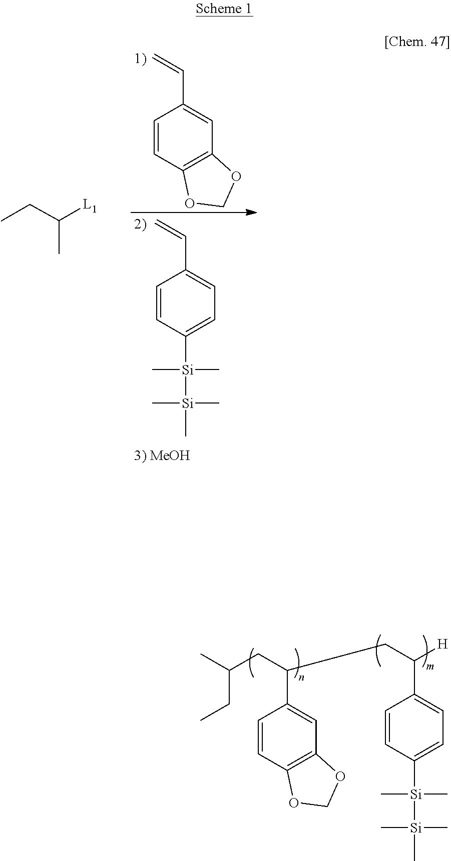

Me represents a methyl group.

Preferably, the silicon-containing polymer or the block containing silicon is poly(4-trimethylsilylstyrene) derived from 4-trimethylsilylstyrene. Preferably, the silicon-containing polymer or the block containing silicon is poly(pentamethyldisilylstyrene) derived from pentamethyldisilylstyrene. The aryl group having 6 to 40 carbon atoms means a monovalent group of a monocyclic or polycyclic aromatic hydrocarbon having 6 to 40 carbon atoms, and specific examples thereof include a phenyl group, a naphthyl group, and an anthryl group.

The entire disclosure described in WO 2020/017494 A is incorporated herein by reference.

In addition, a block copolymer formed of a combination of monomers described below may be used. Styrene, methyl methacrylate, dimethylsiloxane, propylene oxide, ethylene oxide, vinylpyridine, vinylnaphthalene, D,L-lactide, methoxystyrene, methylenedioxystyrene, trimethylsilylstyrene, and pentamethyldisilylstyrene.

A useful block copolymer contains at least two blocks and may be a copolymer such as a diblock, a triblock, or a tetrablock having separate blocks, each of which may be a homopolymer or a random or alternating copolymer.

Examples of a typical block copolymer include polystyrene-b-polyvinylpyridine, polystyrene-b-polybutadiene, polystyrene-b-polyisoprene, polystyrene-b-polymethylmethacrylate, polystyrene-b-polyalkenyl aromatic, polyisoprene-b-polyethylene oxide, polystyrene-b-poly(ethylene-propylene), polyethylene oxide-b-polycaprolactone, polybutadiene-b-polyethylene oxide, polystyrene-b-poly(t-butyl (meth)acrylate), polymethyl methacrylate-b-poly(t-butyl methacrylate), polyethylene oxide-b-polypropylene oxide, polystyrene-b-polytetrahydrofuran, polystyrene-b-polyisoprene-b-polyethylene oxide, poly(styrene-b-dimethylsiloxane), poly(methyl methacrylate-b-dimethylsiloxane), poly(methyl (meth)acrylate-r-styrene)-b-polymethyl methacrylate, poly(methyl (meth)acrylate-r-styrene)-b-polystyrene, poly(p-hydroxystyrene-r-styrene)-b-polymethyl methacrylate, poly(p-hydroxystyrene-r-styrene)-b-polyethylene oxide, polyisoprene-b-polystyrene-b-polyferrocenylsilane, and a combination including at least one type of the block copolymers described above.

In addition, examples of the block copolymer include a block copolymer formed of a combination of organic polymers and/or metal-containing polymers as described below.

A typical organic polymer includes poly(9,9-bis(6′-N,N,N-trimethylammonium)-hexyl)-fluorenphenylene (PEP), poly(4-vinylpyridine) (4PVP), hydroxypropylmethylcellulose (HPMC), polyethylene glycol (PEG), a poly(ethylene oxide)-poly(propylene oxide) diblock or multiblock copolymer, polyvinyl alcohol (PVA), poly(ethylene-vinyl alcohol) (PEVA), polyacrylic acid (PAA), polylactic acid (PLA), poly(ethyloxazoline), poly(alkyl acrylate), polyacrylamide, poly(N-alkylacrylamide), poly(N,N-dialkylacrylamide), polypropylene glycol (PPG), polypropylene oxide (PPO), partially or entirely hydrogenated poly(vinyl alcohol), dextran, polystyrene (PS), polyethylene (PE), polypropylene (PP), polyisoprene (PI), polychloroprene (CR), polyvinyl ether (PVE), polyvinyl acetate (PVA), polyvinyl chloride (PVC), polyurethane (PU), a polyacrylate, a polymethacrylate, oligosaccharides, or polysaccharides, but is not limited thereto.

Examples of the metal-containing polymer include, but are not limited to, a silicon-containing polymer, such as polydimethylsiloxane (PDMS), cage-type silsesquioxane (POSS), or poly(trimethylsilystyrene) (PTMSS)-, or a polymer containing silicon and iron, such as poly(ferrocenyldimethylsilane) (PFS).

Examples of a typical block copolymer (copolymer) include, but are not limited to, a diblock copolymer such as polystyrene-b-polydimethylsiloxane (PS-PDMS), poly(2-vinylpropylene)-b-polydimethylsiloxane (P2VP-PDMS), polystyrene-b-poly(ferrocenyldimethylsilane) (PS-PFS), or polystyrene-b-poly-DL lactic acid (PS-PLA)-, or a triblock copolymer such as polystyrene-b-poly(ferrocenyldimethylsilane)-b-poly(2-vinylpyridine) (PS-PFS-P2VP), polyisoprene-b-polystyrene-b-poly(ferrocenyldimethylsilane) (PI-PS-PFS), or polystyrene-b-poly(ferrocenyldimethylsilane)-b-polystyrene (PS-PTMSS-PS)-. In one example, the PS-PTMSS-PS block copolymer includes a poly(trimethylsilystyrene) polymer block constituted by two chains of PTMSS connected by a linker having four styrene units. Modifications of the block copolymer as disclosed, for example, in US 2012/0046415 A, are also conceivable.

Examples of the other block copolymers include a block copolymer in which a polymer having styrene or a derivative thereof as a structural unit is bonded to a polymer having a (meth)acrylic acid ester as a structural unit, a block copolymer in which a polymer having styrene or a derivative thereof as a structural unit is bonded to a polymer having siloxane or a derivative thereof as a structural unit, and a block copolymer in which a polymer having alkylene oxide as a structural unit is bonded to a polymer having a (meth)acrylic acid ester as a structural unit. Note that the “(meth)acrylic acid ester” means one or both of an acrylic acid ester having a hydrogen atom bonded to the a-position and a methacrylic acid ester having a methyl group bonded to the a-position.

Examples of the (meth)acrylic acid ester include those in which a substituent such as an alkyl group or a hydroxyalkyl group is bonded to a carbon atom of (meth)acrylic acid. Examples of the alkyl group used as the substituent include a linear, branched, or cyclic alkyl group having 1 to 10 carbon atoms. Specific examples of the (meth)acrylic acid ester include methyl (meth)acrylate, ethyl (meth)acrylate, propyl (meth)acrylate, cyclohexyl (meth)acrylate, octyl (meth)acrylate, nonyl (meth)acrylate, hydroxyethyl (meth)acrylate, hydroxypropyl (meth)acrylate, benzyl (meth)acrylate, anthracene (meth)acrylate, glycidyl (meth)acrylate, 3,4-epoxycyclohexylmethane (meth)acrylate, and propyltrimethoxysilane (meth)acrylate.

Examples of the derivative of styrene include a-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

Examples of the derivative of siloxane include dimethylsiloxane, diethylsiloxane, diphenylsiloxane, and methylphenylsiloxane.

Examples of the alkylene oxide include ethylene oxide, propylene oxide, isopropylene oxide, and butylene oxide.

Examples of the block copolymer include a polystyrene/poly(methyl methacrylate) block copolymer, a styrene-polyethyl methacrylate block copolymer, a styrene-(poly-t-butyl methacrylate) block copolymer, a styrene-polymethacrylic acid block copolymer, a styrene-polymethyl acrylate block copolymer, a styrene-polyethyl acrylate block copolymer, a styrene-(poly-t-butyl acrylate) block copolymer, and a styrene-polyacrylic acid block copolymer.

The entire disclosure described in WO 2022/039187 A is incorporated herein by reference.

### <<<Solvent>>>

Examples of the solvent used in the self-assembled film-forming composition include the following organic solvents.
Aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane
Aromatic hydrocarbon-based solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene
Monoalcohol-based solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol
Polyhydric alcohol-based solvents such as ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, and glycerin
Ketone-based solvents such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone
Ether-based solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran
Ester-based solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate
Nitrogen-containing solvents such as N-methylformamide, N,N-dimethylformamide, N,N-diethylformamide, acetamide, N-methylacetamide, N,N-dimethylacetamide, N-methylpropionamide, and N-methylpyrrolidone
Sulfur-containing solvents such as dimethyl sulfide, diethyl sulfide, thiophene, tetrahydrothiophene, dimethyl sulfoxide, sulfolane, and 1,3-propane sultone

In particular, propylene glycol monomethyl ether, propylene glycol monoethyl ether, propylene glycol monopropyl ether, propylene glycol monobutyl ether, propylene glycol dimethyl ether, propylene glycol diethyl ether, propylene glycol monomethyl ether acetate, propylene glycol monoethyl ether acetate, and propylene glycol monopropyl ether acetate are preferable from the viewpoint of the storage stability of the solution of the composition.

In addition, the solvent contained in the self-assembled film-forming composition may be a combination of a low-boiling-point solvent (A) having a boiling point of 160° C. or lower and a high-boiling-point solvent (B) having a boiling point of 170° C. or higher as described in WO 2018/135456 A.

As the low-boiling-point solvent (A) having a boiling point of 160° C. or lower, for example, propylene glycol monomethyl ether acetate (boiling point: 146° C.), n-butyl acetate (boiling point: 126° C.), and methyl isobutyl ketone (boiling point: 116° C.) are preferable.

As the high-boiling-point solvent (B) having a boiling point of 170° C. or higher, for example, N-methylpyrrolidone (boiling point: 204° C.), diethylene glycol monomethyl ether (boiling point: 193° C.), N,N-dimethylisobutyramide (boiling point: 175° C.), 3-methoxy-N,N-dimethylpropanamide (boiling point: 215° C.), and γ-butyrolactone (boiling point: 204° C.) are preferable.

Two or more types of each of the low-boiling-point solvent (A) and the high-boiling-point solvent (B) can be selected and mixed for use.

In a preferred aspect, the high-boiling-point solvent (B) is contained in an amount of 0.3 to 2.0 wt % with respect to the total amount of the solvent contained in the composition. Most preferably, the high-boiling-point solvent (B) is contained in an amount of 0.5 to 1.5 wt %.

The entire disclosure described in WO 2018/135456 A is incorporated herein by reference.

### <<Phase Separation of Self-Assembled Film>>

The phase separation of the self-assembled film (for example, a film of a block copolymer) can be performed by a treatment that results in realignment of the self-assembled film, for example, a sonication treatment, a solvent treatment, thermal annealing, or the like. In many applications, it is desirable to achieve phase separation of the self-assembled film simply by heating or so-called thermal annealing.

The thermal annealing can be performed under normal pressure, reduced pressure, or pressurized conditions in the air or in an inert gas.

The conditions for the thermal annealing are not particularly limited, and are preferably 180° C. to 300° C., more preferably 210° C. to 280° C., and particularly preferably 230° C. to 270° C., in the air.

The treatment time is not particularly limited, and is usually 1 minute to 30 minutes, and preferably 3 minutes to 10 minutes.

The phase separation of the self-assembled film forms a domain oriented substantially perpendicular to the substrate or underlayer film surface. The form of the domain is, for example, a lamellar shape, a spherical shape, a cylindrical shape, or the like. A domain interval is, for example, 50 nm or less.

### <<Patterning of Self-Assembled Film>>

By selectively removing a part of the phase-separated self-assembled film, a pattern according to the form of the domain is obtained.

Examples of the method for selectively removing the part of the phase-separated self-assembled film include a method in which the phase-separated self-assembled film is subjected to an oxygen plasma treatment and a method in which the phase-separated self-assembled film is subjected to a hydrogen plasma treatment.

### <Sixth Step>

The sixth step is a step of forming a brush layer in a gap of a pattern of the patterned underlayer film.

The sixth step is a step performed between the fourth step and the fifth step.

The method for forming the brush layer is not particularly limited, and examples thereof include a method in which a brush layer-forming composition is applied and dried.

### <<Brush Layer-Forming Composition>>

The brush layer-forming composition contains, for example, a brush polymer and a solvent.

The brush layer-forming composition is, for example, a composition containing a polymer chain capable of directly binding to a substrate surface. A film or a layer formed by arranging a polymer chain on a substrate in a brush shape may be referred to as a brush layer.

The brush layer-forming composition is, for example, an underlayer film-forming composition for forming an underlayer film of a layer containing a block copolymer.

In addition, the film formed of the brush layer-forming composition serves as, for example, a guide for controlling a generation position of a polymer phase formed by self-assembly. For example, the film formed of the brush layer-forming composition has an uneven structure, and is a side wall of a concave portion in a physical guide (grapho-epitaxy) for forming a microphase separation pattern in the concave portion. In addition, for example, the film formed of the brush layer-forming composition is a chemical guide (chemical-epitaxy) that is formed in an underlayer of a self-assembled material and controls a formation position of the microphase separation pattern based on a difference in surface energy.

### <<<Brush Polymer>>>

The brush polymer is not particularly limited as long as it is a brush polymer used for forming an underlayer film.

Examples of the brush polymer include a polymer contained in a neutral wet bottom surface described in JP 2011-515537 A. Examples of such a polymer include a random copolymer described in claim 15 of JP 2011-515537 A and a grafted blend of a plurality of homopolymers described in claim 16 of JP 2011-515537 A. The contents of JP 2011-515537 A are hereby incorporated in their entireties by reference, to the extent that they have been disclosed herein.

Other examples of the brush polymer include a random copolymer described in JP 2011-518652 A. An example of the random copolymer described in JP 2011-518652 A is photocrosslinkable random PS-r-PMMA described in paragraph [0028]. The contents of JP 2011-518652 A are hereby incorporated in their entireties by reference, to the extent that they have been disclosed herein.

Other examples of the brush polymer include a resin in which 20 mol % to 80 mol % of structural units of all structural units are structural units derived from an aromatic ring-containing monomer. Such a resin is, for example, a resin component contained in a primer described in WO 2012/036121 A. The contents of WO 2012/036121 A are hereby incorporated in their entireties by reference, to the extent that they have been disclosed herein.

Other examples of the brush polymer include a random copolymer described in claim 1 of JP 2013-166934 A. The contents of JP 2013-166934 A are hereby incorporated in their entireties by reference, to the extent that they have been disclosed herein.

Other examples of the brush polymer include a polymer having 0.2 mol % or more of a unit structure of a polycyclic aromatic vinyl compound with respect to all unit structures. Examples of such polymers include a polymer contained in an underlayer film-forming composition described in WO 2014/097993 A. The contents of WO 2014/097993 A are hereby incorporated in their entireties by reference, to the extent that they have been disclosed herein.

Other examples of the brush polymer include a polymer [for example, poly(alkyl acrylate) containing a functional group capable of reacting with a semiconductor substrate]contained in a brush backfill composition described in JP 2015-130496 A. The contents of JP 2015-130496 A are hereby incorporated in their entireties by reference, to the extent that they have been disclosed herein.

Other examples of the brush polymer include an addition polymer described in claim 1 of JP 2016-148024 A. The contents of JP 2016-148024 A are hereby incorporated in their entireties by reference, to the extent that they have been disclosed herein.

Other examples of the brush polymer include a polymer contained in a pinning material described in claim 1 of JP 2016-528713 A. Examples of such a polymer include a polymer described in claim 3 of JP 2016-528713 A. The contents of JP 2016-528713 A are hereby incorporated in their entireties by reference, to the extent that they have been disclosed herein.

Other examples of the brush polymer include an acid-sensitive copolymer containing an acid-decomposable group, an attachment group, and a functional group described in claim 1 of JP 2018-139007 A. The contents of JP 2018-139007 A are hereby incorporated in their entireties by reference, to the extent that they have been disclosed herein.

Other examples of the brush polymer include a hydrophobic polymer brush precursor described in claim 1 of JP 2018-503241 A. The contents of JP 2018-503241 A are hereby incorporated in their entireties by reference, to the extent that they have been disclosed herein.

The brush polymer preferably contains a functional group capable of binding to a substrate.

Examples of the functional group capable of binding to the substrate include a hydroxy group, an amino group, and a sulfonic acid group.

The brush polymer may contain a functional group capable of binding to a substrate at a terminal of a polymer chain or at a location other than the terminal of the polymer chain.

A method for introducing a functional group capable of binding to a substrate into a terminal of a polymer chain is not particularly limited, and examples thereof include a method using a compound containing a functional group capable of binding to a substrate in a polymerization initiator or a chain transfer agent in a case of an addition polymerization type polymer.

The brush polymer is preferably an addition polymerization type polymer.

The addition polymerization type polymer is obtained by, for example, polymerizing one or more types of radically polymerizable monomers.

The radically polymerizable monomer is not particularly limited, and examples thereof include a (meth)acrylic compound and an aromatic group-containing vinyl compound.

Examples of the (meth)acrylic compound include (meth)acrylic acid and (meth)acrylic acid ester. Examples of the (meth)acrylic acid ester include methyl (meth)acrylate, ethyl (meth)acrylate, methyl (meth)acrylate, ethyl (meth)acrylate, propyl (meth)acrylate, isopropyl (meth)acrylate, n-butyl (meth)acrylate, sec-butyl (meth)acrylate, and tert-butyl (meth)acrylate.

Examples of the aromatic group-containing vinyl compound include styrene, a-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

### <<<<Polymer (P)>>>>

The brush polymer is preferably a polymer (P) containing the following structural units (A) and (B) from the viewpoint of being able to induce a microphase separation structure of the block copolymer perpendicularly to the substrate.

Structural unit (A): A structural unit derived from a (meth)acrylic compound containing a (meth)acryloyl group and a functional group capable of binding to a substrate Structural unit (B): A structural unit derived from an aromatic group-containing vinyl compound

A molar ratio of the structural unit (A) to all structural units in the polymer (P) is more than 0% and 5% or less.

When the molar ratio of the structural unit (A) to all structural units in the polymer (P) is more than 0% and 5% or less, a film that induces a microphase separation structure of the block copolymer perpendicularly to the substrate can be formed. When the molar ratio of the structural unit (A) to all structural units in the polymer (P) is more than 5%, the alignment of the microphase separation structure of the block copolymer is disturbed, and the microphase separation structure of the block copolymer cannot be induced perpendicularly to the substrate.

The polymer (P) is not particularly limited as long as it contains the structural units (A) and (B), and is preferably an addition polymer obtained by polymerization of a compound having a polymerizable unsaturated group. Examples of the polymerizable unsaturated group include an ethylenically unsaturated group. Examples of the ethylenically unsaturated group include a vinyl group, an allyl group, a propargyl group, a butenyl group, an ethynyl group, a phenylethynyl group, a maleimide group, a nadiimide group, and a (meth)acryloyl group.

The polymer (P) is, for example, a random copolymer.

The polymer (P) may contain a structural unit other than the structural units (A) and (B).

The structural unit (A) is a structural unit derived from a (meth)acrylic compound.

The (meth)acrylic compound has a (meth)acryloyl group.

The (meth)acrylic compound contains a functional group capable of binding to a substrate.

The (meth)acryloyl group is a notation indicating an acryloyl group and a methacryloyl group. The acryloyl group refers to a group represented by CH₂═CH—CO—, and the methacryloyl group refers to a group represented by CH₂═C(CH₃)—CO—.

Examples of the functional group capable of binding to the substrate include, but are not limited to, a hydroxy group, an amino group, and a sulfonic acid group.

The number of functional groups capable of binding to a substrate in the structural unit (A) may be 1 or 2 or more, and is preferably 1.

The number of (meth)acryloyl groups in the (meth)acrylic compound may be 1 or 2 or more, and is preferably 1.

The structural unit (A) is a structural unit different from the structural unit (B). Therefore, the structural unit (B) does not have an aromatic ring.

The structural unit (A) in the polymer (P) may be of one type or two or more types.

The structural unit (A) preferably includes a structural unit (A-1) represented by formula (1) below.

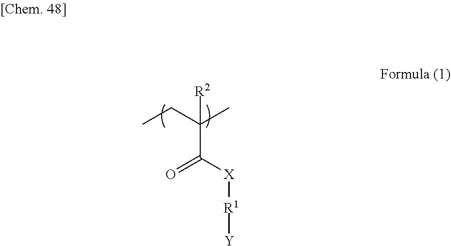

In formula (1), X¹ represents —O— or —NH—, Y represents a hydroxy group, an amino group, or a sulfonic acid group, R¹ represents an alkylene group that has 1 to 10 carbon atoms and may be substituted with a halogen atom, and R² represents a hydrogen atom or a methyl group.

The amino group is preferably a primary amino group or a secondary amino group.

The primary amino group refers to a monovalent functional group (—NH₂) obtained by removing a hydrogen atom from ammonia.

The secondary amino group refers to a monovalent functional group (—NHR (in the formula, R represents an organic group)) obtained by removing a hydrogen atom from a primary amine. R represents, for example, an alkyl group having 1 to 6 carbon atoms.

The alkylene group that has 1 to 10 carbon atoms and may be substituted with a halogen atom may be linear, branched, or cyclic.

Examples of the halogen atom include a fluorine atom, a chlorine atom, a bromine atom, and an iodine atom.

The number of halogen atoms in the alkylene group that has 1 to 10 carbon atoms and is substituted with a halogen atom may be 1 or 2 or more.

The alkylene group having 1 to 10 carbon atoms may be a linear or branched alkylene group, and examples thereof include a methylene group, an ethylene group, a 1,3-propylene group (trimethylene group), a 1-methylethylene group (1,2-propylene group), a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethylocylene group, a 1,9-nonylene group, and a 1,10-decylene group.

The molar ratio of the structural unit (A) to all structural units in the polymer (P) is more than 0% and 5% or less, preferably 0.1% or more and 5% or less, more preferably 0.3% or more and 4.5% or less, and particularly preferably 0.5% or more and 4.0% or less.

Examples of the (meth)acrylic compound include a compound represented by formula (1-1) below.

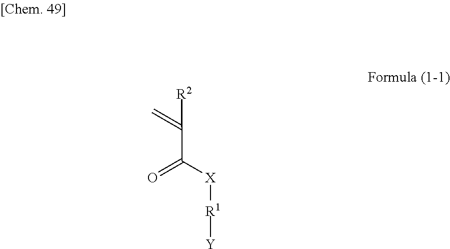

In formula (1-1), X¹ represents —O— or —NH—. Y represents a hydroxy group, an amino group, or a sulfonic acid group, R¹ represents an alkylene group that has 1 to 10 carbon atoms and may be substituted with a halogen atom, and R² represents a hydrogen atom or a methyl group.

Examples of the (meth)acrylic compound include hydroxy group-containing (meth)acrylate, amino group-containing (meth)acrylate, sulfonic acid group-containing (meth)acrylate, hydroxy group-containing (meth)acrylamide, and sulfonic acid group-containing (meth)acrylamide.

Examples of the hydroxy group-containing (meth)acrylate include 2-hydroxyethyl (meth)acrylate, 2-hydroxypropyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, and 1,4-cyclohexanedimethanol mono(meth)acrylate.

Examples of the amino group-containing (meth)acrylate include a primary amino group-containing (meth)acrylate and a secondary amino group-containing (meth)acrylate.

Examples of the primary amino group-containing (meth)acrylate include aminomethyl (meth)acrylate and aminoethyl (meth)acrylate.

Examples of the secondary amino group-containing (meth)acrylate include t-butylaminoethyl (meth)acrylate and t-butylaminopropyl (meth)acrylate.

Examples of the sulfonic acid group-containing (meth)acrylate include 2-sulfoethyl (meth)acrylate and 3-sulfopropyl (meth)acrylate.

Examples of the hydroxy group-containing (meth)acrylamide include N-(hydroxymethyl) (meth)acrylamide, N-(2-hydroxyethyl) (meth)acrylamide, and N-(4-hydroxybutyl) (meth)acrylamide.

The structural unit (B) is a structural unit derived from an aromatic group-containing vinyl compound.

The aromatic ring of the aromatic group-containing vinyl compound may be an aromatic hydrocarbon ring or may be an aromatic heterocyclic ring, and an aromatic hydrocarbon ring is preferable.

Examples of the aromatic hydrocarbon ring include a benzene ring, a naphthalene ring, and an anthracene ring.

The aromatic group-containing vinyl compound does not contain, for example, a functional group capable of binding to a substrate.

The aromatic group-containing vinyl compound does not contain, for example, a hydroxy group, an amino group, and a sulfonic acid group.

The structural unit (B) does not contain, for example, a functional group capable of binding to a substrate.

The structural unit (B) does not contain, for example, a hydroxy group, an amino group, and a sulfonic acid group.

The structural unit (B) in the polymer (P) may be of one type or two or more types.

The structural unit (B) preferably includes a structural unit (B-1) represented by formula (2) below.

The structural unit (B) preferably includes a structural unit (B-2) represented by formula (3) below.

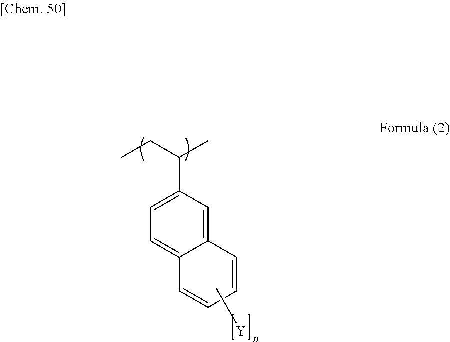

In formula (2), n Y's each independently represent a halogen atom, an alkyl group, an alkoxy group, an alkoxycarbonyl group, or a thioalkyl group, and n represents an integer of 0 to 7.

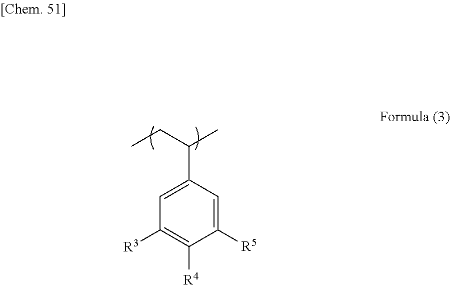

In formula (3), R³ to R⁵ each independently represent a hydrogen atom or a tert-butyl group, provided that one or two of R³ to R⁵ represent a tert-butyl group.

Examples of the halogen atom in Y in formula (2) include a fluorine atom, a chlorine atom, a bromine atom, and an iodine atom.

The alkyl group in Y in formula (2) is preferably an alkyl group having 1 to 15 carbon atoms, more preferably an alkyl group having 1 to 10 carbon atoms, still more preferably an alkyl group having 1 to 6 carbon atoms, and particularly preferably an alkyl group having 1 to 3 carbon atoms. The alkyl group may be linear, branched, or cyclic.

The alkoxy group in Y in formula (2) is preferably an alkoxy group having 1 to 15 carbon atoms, more preferably an alkoxy group having 1 to 10 carbon atoms, still more preferably an alkoxy group having 1 to 6 carbon atoms, and particularly preferably an alkoxy group having 1 to 3 carbon atoms. The alkyl group in the alkoxy group may be linear, branched, or cyclic.

The alkoxycarbonyl group in Y in formula (2) is preferably an alkoxycarbonyl group having 2 to 15 carbon atoms, more preferably an alkoxycarbonyl group having 2 to 10 carbon atoms, still more preferably an alkoxycarbonyl group having 2 to 6 carbon atoms, and particularly preferably an alkoxycarbonyl group having 2 to 3 carbon atoms. The alkyl group in the alkoxycarbonyl group may be linear, branched, or cyclic.

Examples of the thioalkyl group in Y in formula (2) include a group in which —O— of the alkoxy group is substituted with —S—.

A molar ratio of the structural unit (B) to all structural units in the polymer (P) is not particularly limited, and is preferably 80% or more and less than 100%, more preferably 90% or more and less than 100%, and particularly preferably more than 95% and less than 100%.

A molar ratio of the structural unit (A) to the structural unit (B) (structural unit (A):structural unit (B)) in the polymer (P) is not particularly limited, and is preferably 1:200 to 1:10, and more preferably 1:150 to 1:20.

When the polymer (P) contains the structural unit (B-1) represented by formula (2), a molar ratio of the structural unit (A) to the structural unit (B-1) (structural unit (A):structural unit (B-1)) in the polymer (P) is not particularly limited, and is preferably 1:100 to 1:5, and more preferably 1:75 to 1:10.

When the polymer (P) contains the structural unit (B-2) represented by formula (3), a molar ratio of the structural unit (A) to the structural unit (B-2) (structural unit (A):structural unit (B-2)) in the polymer (P) is not particularly limited, and is preferably 1:100 to 1:5, and more preferably 1:75 to 1:10.

When the polymer (P) contains the structural unit (B-1) represented by formula (2) and the structural unit (B-2) represented by formula (3), a molar ratio of the structural unit (B-1) to the structural unit (B-2) in the polymer (P) (structural unit (B-1):structural unit (B-2)) is not particularly limited, and is preferably 1.0:0.1 to 0.1:1.0, more preferably 1.0:0.5 to 0.5:1.0, and particularly preferably 1.0:0.7 to 0.7:1.0.

Examples of the aromatic group-containing vinyl compound include a compound represented by formula (2-1) below and a compound represented by formula (3-1) below.

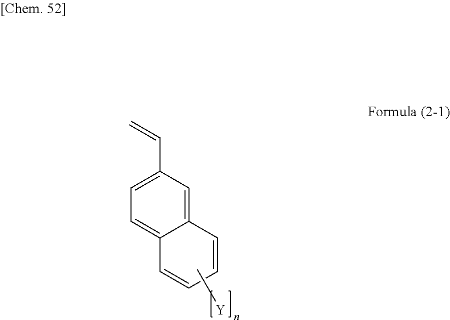

In formula (2-1), n Y's each independently represent a halogen atom, an alkyl group, an alkoxy group, an alkoxycarbonyl group, or a thioalkyl group, and n represents an integer of 0 to 7.

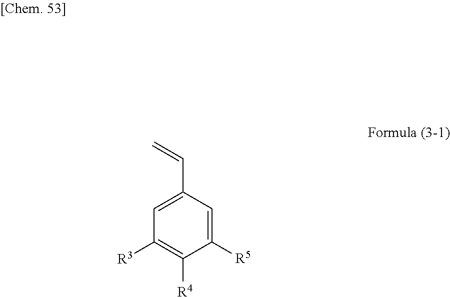

In formula (3-1), R³ to R⁵ each independently represent a hydrogen atom or a tert-butyl group, provided that one or two of R³ to R⁵ represent a tert-butyl group.

A weight average molecular weight of the brush polymer measured by a gel permeation chromatography (Gel Permeation Chromatography, GPC) method is not particularly limited, and is, for example, 1,000 to 50,000 and preferably 2,000 to 20,000 in terms of polystyrene.

### <<<<Method for Producing Brush Polymer>>>>

A method for producing the brush polymer is not particularly limited.

For example, when the brush polymer is an addition polymerization type polymer, the brush polymer can be produced by polymerizing a monomer by a conventional method, for example, bulk polymerization, solution polymerization, suspension polymerization, or emulsion polymerization. Solution polymerization is particularly preferable, and in this case, for example, polymerization can be performed by adding a desired monomer to a solvent to which a polymerization initiator is added.

For example, when the brush polymer is an addition polymerization type random copolymer, the brush polymer can be produced by copolymerizing various monomers by a conventional method such as bulk polymerization, solution polymerization, suspension polymerization, or emulsion polymerization so as to be copolymerized in an appropriate molar ratio.

Examples of such polymerization include radical polymerization.

The method for producing the brush polymer may be a production method by a polymerization method other than radical polymerization. For example, the production method may be a production method by ionic (anionic or cationic) addition polymerization, or a production method by a polycondensation or polyaddition reaction.

The polymer (P) can be produced, for example, by solution polymerization of a monomer mixture containing a (meth)acrylic compound containing a (meth)acryloyl group and a functional group capable of binding to a substrate, and an aromatic group-containing vinyl compound.

### [Polymerization Initiator]

As the polymerization initiator, an organic peroxide or a diazo-based compound can be used.

Examples of the organic peroxide include diacyl peroxides, peroxydicarbonates, peroxyesters, and sulfonates.

Examples of the diacyl peroxides include diacetyl peroxide, diisobutyl peroxide, didecanoyl peroxide, benzoyl peroxide, and succinic acid peroxide.

Examples of the peroxydicarbonates include diisopropyl peroxydicarbonate, di-2-ethylhexyl peroxydicarbonate, and diallyl peroxydicarbonate.

Examples of the peroxyesters include tert-butyl peroxyisobutyrate, tert-butyl neodecanoate, and cumene peroxy neodecanoate.

Examples of the sulfonate peroxides include acetylcyclohexylsulfonyl peroxide.

Examples of the diazo-based compound include 2,2′-azobisisobutyronitrile, 4,4′-azobis(4-cyanovaleric acid), 2,2′-azobis(4-methoxy-2,4-dimethylvaleronitrile), and 2,2′-azobis(2-cyclopropyl propionitrile).

When it is desired to terminate the polymerization in a short time, it is preferable to use a polymerization initiator having a decomposition half-life at 80° C. of 10 hours or less. As such a polymerization initiator, benzoyl peroxide and 2,2′-azobisisobutyronitrile are preferable, and 2,2′-azobisisobutyronitrile is more preferable.

The amount of the polymerization initiator used is, for example, 0.0001 to 0.2 equivalents, preferably 0.0005 to 0.1 equivalents, with respect to the total amount of monomers used.

### [Solvent]

The solvent used for the polymerization is not particularly limited as long as it is a solvent that is not involved in the polymerization reaction and is compatible with the resulting brush polymer, and examples thereof include aromatic hydrocarbons, alicyclic hydrocarbons, aliphatic hydrocarbons, ketones, ethers, esters, amides, sulfoxides, alcohols, and polyhydric alcohol derivatives.

Examples of the aromatic hydrocarbons include benzene, toluene, and xylene.

Examples of the alicyclic hydrocarbons include cyclohexane.

Examples of the aliphatic hydrocarbons include n-hexane and n-octane.

Examples of the ketones include acetone, methyl ethyl ketone, and cyclohexanone.

Examples of the ethers include tetrahydrofuran and dioxane.

Examples of the esters include ethyl acetate and butyl acetate.

Examples of the amides include N,N-dimethylformamide and N,N-dimethylacetamide.

Examples of the sulfoxides include dimethyl sulfoxide.

Examples of the alcohols include methanol and ethanol.

Examples of the polyhydric alcohol derivatives include ethylene glycol monomethyl ether, ethylene glycol monomethyl ether acetate, and propylene glycol monomethyl ether acetate.

One type of these can be used alone or two or more types thereof can be used in combination.

The polymerization temperature is not particularly limited as long as a side reaction such as a transfer reaction or a stop reaction does not occur and is in a temperature range in which the monomer is consumed and the polymerization is completed, and the polymerization is preferably performed in a temperature range of −100° C. or higher and the solvent boiling point or lower.

In addition, a concentration of the monomer in the solvent is not particularly limited, and is usually 1 to 40 mass % and preferably 10 to 30 wt %.

The time for the polymerization reaction can be appropriately selected, and is usually in a range of 2 hours to 50 hours.

### <<<Solvent>>>

The solvent contained in the brush layer-forming composition is not particularly limited as long as it is a solvent that dissolves the brush polymer.

Examples of the solvent include propylene glycol monomethyl ether (PGME), propylene glycol monomethyl ether acetate (PGMEA), propylene glycol monopropyl ether, methyl ethyl ketone, ethyl lactate, cyclohexanone, N,N-2-trimethyl propionamide, γ-butyrolactone, N-methyl-2-pyrrolidone, methyl 2-hydroxyisobutyrate, and ethyl 3-ethoxypropionate.

One type of these can be used alone or two or more types thereof can be used in combination.

A content of the solvent in the brush layer-forming composition is not particularly limited, and is, for example, 90 mass % or more and 99.9 mass % or less.

### <<<Another Component>>>

It is preferable that the brush layer-forming composition does not contain a crosslinking agent. For example, the brush polymer is allowed to react with the substrate so that the film obtained using the brush layer-forming composition becomes a film that is not dissolved in a solvent contained in a self-assembled film-forming composition containing a block copolymer. Therefore, the brush layer-forming composition does not need to contain a crosslinking agent.

In the present invention, the phrase “does not contain a crosslinking agent” may include that a crosslinking agent is slightly contained to such an extent that the crosslinking agent does not sufficiently play a role as a crosslinking agent. In an aspect in which the brush layer-forming composition does not contain a crosslinking agent, a content of the crosslinking agent in the brush layer-forming composition is preferably less than 0.1 mass %, more preferably 0.01 mass % or less, and particularly preferably 0.001 mass % or less, with respect to the brush polymer.

Examples of the crosslinking agent include a nitrogen-containing compound containing two to four nitrogen atoms substituted with a methylol group or an alkoxymethyl group.

Examples of the crosslinking agent include hexamethoxymethylmelamine, tetramethoxymethyl glycoluril, tetramethoxymethylbenzoguanamine, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

The brush layer-forming composition may contain a surfactant. The surfactant is an additive for improving applicability onto a substrate.

As the surfactant, a known surfactant such as a nonionic surfactant or a fluorine-based surfactant can be used.

A content of the surfactant in the brush layer-forming composition is, for example, 0.1 mass % to 5 mass % with respect to the brush polymer.

In the brush layer-forming composition, when a component excluding a solvent is defined as a solid content, the solid content includes a brush polymer and an additive added as necessary.

A concentration of the solid content in the brush layer-forming composition is not particularly limited, and is, for example, 0.1 mass % to 15 mass % and preferably 0.1 mass % to 10 mass %.

An example of the method for producing a semiconductor element of the present invention will be described with reference to the drawings.

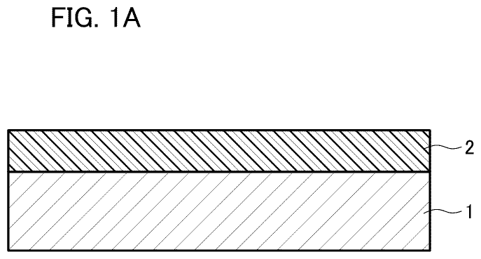

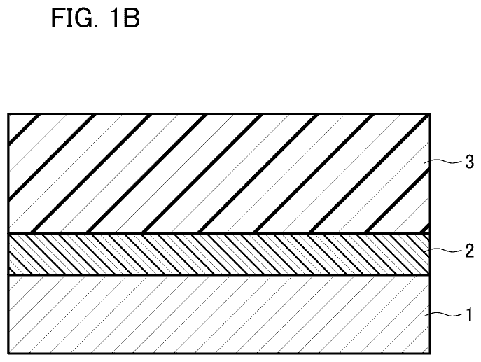

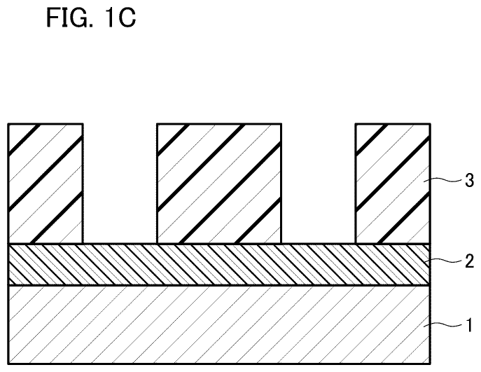

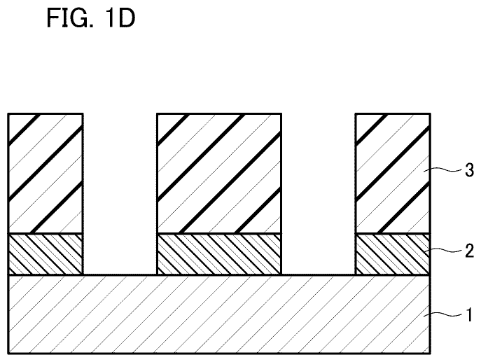

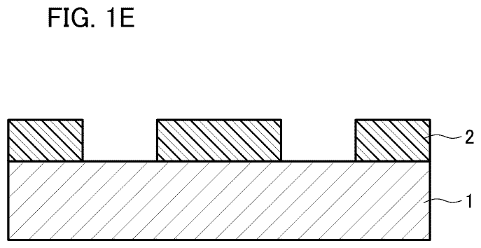

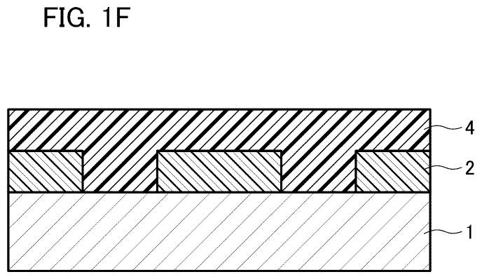

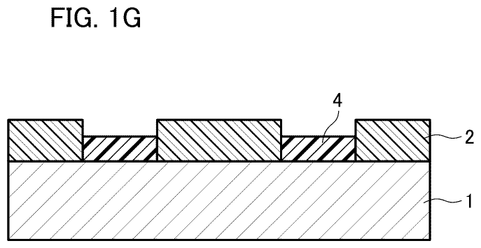

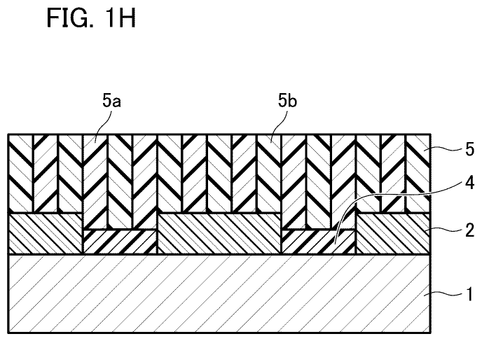

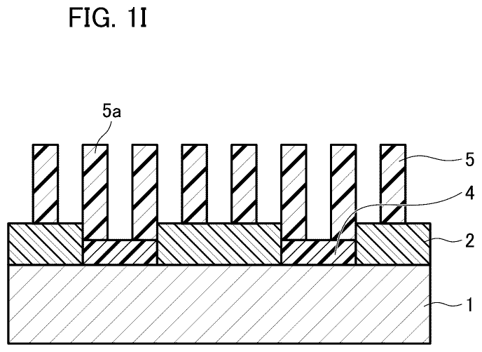

FIGS. 1A to 1I are schematic cross-sectional views for explaining an example of the method for producing a semiconductor element of the present invention.

An underlayer film 2 is formed on a semiconductor substrate 1 using the underlayer film-forming composition of the present invention (FIG. 1A).

Subsequently, a resist film 3 is formed on the underlayer film 2 (FIG. 1B).

Subsequently, the resist film 3 is irradiated with light or an electron beam, and then the resist film 3 is developed to obtain a resist pattern (the resist film 3 in a pattern form) (FIG. 1C).

Subsequently, the underlayer film 2 is etched using the resist pattern (the resist film 3 in a pattern form) as a mask to form a patterned underlayer film 2 (FIG. 1D).

Subsequently, the resist pattern (the resist film 3 in a pattern form) is removed (FIG. 1E).

Subsequently, a brush layer-forming composition is applied onto the semiconductor substrate 1 and the patterned underlayer film 2 to form a brush layer 4 (FIG. 1F).

Subsequently, a part of the brush layer 4 is removed to form the brush layer 4 in a gap of the pattern of the patterned underlayer film 2 (FIG. 1G).

Subsequently, a self-assembled film 5 is formed on the patterned underlayer film 2 and the brush layer 4. The self-assembled film 5 is, for example, a film of a block copolymer having a block A and a block B. By phase-separating the self-assembled film 5, a microphase separation structure having domains 5a of the block A and domains 5b of the block B is obtained (FIG. 1H).

By selectively removing a part (for example, the domains 5b of the block B) of the microphase-separated self-assembled film 5, a pattern according to the form of the microphase separation domains is obtained (FIG. 1I).

Although not illustrated, examples of an additional step include a step of processing the semiconductor substrate using a pattern according to the form of the microphase separation domains as a mask or using the underlayer film 2 and the brush layer 4 to which the pattern is transferred as a mask.

### EXAMPLES

Next, the contents of the present invention will be specifically described with reference to Examples, but the present invention is not limited thereto.

The weight average molecular weights of the polymers shown in the following Synthesis Examples 1 to 7 and Comparative Synthesis Examples 1 to 3 in the present description are the measurement results by gel permeation chromatography (hereinafter, abbreviated as GPC). In the measurement, a GPC apparatus manufactured by Tosoh Corporation was used, and measurement conditions and the like are as follows:
GPC column: TSKgel Super-Multipore HZ-N (Two columns)
Column temperature: 40° C.
Solvent: Tetrahydrofuran (THF)
Flow rate: 0.35 ml/min
Standard sample: polystyrene (manufactured by Tosoh Corporation)

### Synthesis Example 1

In 32.00 g of propylene glycol monomethyl ether acetate, 5.68 g (molar ratio relative to the whole polymer 1:75%) of 2-vinylnaphthalene, 1.60 g (molar ratio relative to the whole polymer 1:25%) of 2-hydroxyethyl methacrylate, and 0.73 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and a precipitate was recovered by suction filtration, and then dried at 60° C. under reduced pressure to recover a polymer 1. The weight average molecular weight Mw measured by GPC in terms of polystyrene was 8,500. The structure present in the polymer 1 is represented by the following formula.

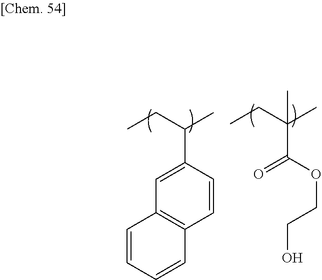

### Synthesis Example 2

In 40.00 g of propylene glycol monomethyl ether acetate, 4.75 g (molar ratio relative to the whole polymer 2: 55%) of 2-vinylnaphthalene, 2.96 g (molar ratio relative to the whole polymer 2: 30%) of benzyl methacrylate, 1.21 g (molar ratio relative to the whole polymer 2: 15%) of 2-hydroxypropyl methacrylate, and 1.07 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and a precipitate was recovered by suction filtration, and then dried at 60° C. under reduced pressure to recover a polymer 2. The weight average molecular weight Mw measured by GPC in terms of polystyrene was 5,900. The structure present in the polymer 2 is represented by the following formula.

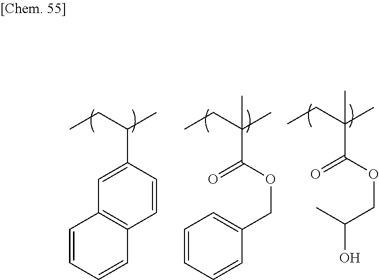

### Synthesis Example 3

In 24.00 g of propylene glycol monomethyl ether acetate, 2.94 g (molar ratio relative to the whole polymer 3: 50%) of 2-vinylnaphthalene, 1.24 g (molar ratio relative to the whole polymer 3: 25%) of hydroxyethyl methacrylate, 1.71 g (molar ratio relative to the whole polymer 3: 25%) of N-cyclohexylmaleimide, and 0.12 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and a precipitate was recovered by suction filtration, and then dried at 60° C. under reduced pressure to recover a polymer 3. The weight average molecular weight Mw measured by GPC in terms of polystyrene was 16,300. The structure present in the polymer 3 is represented by the following formula.

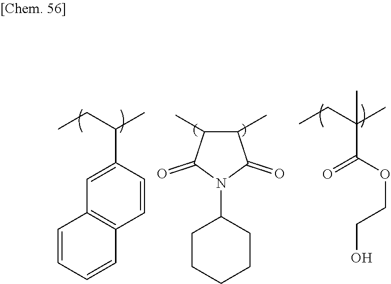

### Synthesis Example 4

In 24.00 g of propylene glycol monomethyl ether acetate, 2.86 g (molar ratio relative to the whole polymer 4: 50%) of 2-vinylnaphthalene, 1.68 g (molar ratio relative to the whole polymer 4: 25%) of N-cyclohexylmaleimide, 1.32 g (molar ratio relative to the whole polymer 4: 25%) of N-hydroxyethylmaleimide, and 0.12 g of 2,2′-azobisisobutyronitrile were dissolved. A reaction vessel was purged with nitrogen, and then the solution was heated and stirred at 140° C. for about 4 hours. This reaction solution was added dropwise to isopropyl alcohol, and a precipitate was recovered by suction filtration, and then dried at 60° C. under reduced pressure to recover a polymer 4. The weight average molecular weight Mw measured by GPC in terms of polystyrene was 11,900. The structure present in the polymer 4 is represented by the following formula.

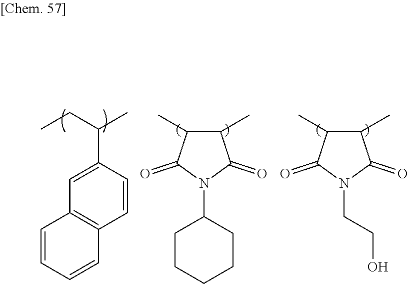

### Synthesis Example 5

In 40.00 g of propylene glycol monomethyl ether acetate, 7.03 g (molar ratio relative to the whole polymer 5: 71%) of 2-vinylnaphthalene, 0.87 g (molar ratio relative to the whole polymer 5:10%) of 4-methoxystyrene, 1.77 g (molar ratio relative to the whole polymer 5:19%) of 2-hydroxypropyl methacrylate, and 0.49 g of 2,2′-azobisisobutyronitrile were dissolved. A reaction vessel was purged with nitrogen, and then the solution was heated and stirred at 140° C. for about 4 hours. The reaction solution was added dropwise to methanol, and a precipitate was recovered by suction filtration and then dried at 60° C. under reduced pressure to recover a polymer 5. The weight average molecular weight Mw measured by GPC in terms of polystyrene was 7,200. The structure present in the polymer 5 is represented by the following formula.

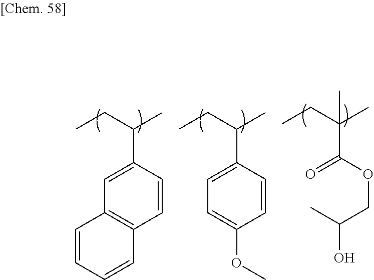

### Synthesis Example 6

In 40.00 g of propylene glycol monomethyl ether acetate, 7.22 g (molar ratio relative to the whole polymer 6: 71%) of 2-vinylnaphthalene, 0.50 g (molar ratio relative to the whole polymer 6: 10%) of 4-tert-butylstyrene, 1.80 g (molar ratio relative to the whole polymer 6: 19%) of 2-hydroxypropyl methacrylate, and 0.48 g of 2,2′-azobisisobutyronitrile were dissolved. A reaction vessel was purged with nitrogen, and then the solution was heated and stirred at 140° C. for about 4 hours. The reaction solution was added dropwise to methanol, and a precipitate was recovered by suction filtration and then dried at 60° C. under reduced pressure to recover a polymer 6. The weight average molecular weight Mw measured by GPC in terms of polystyrene was 7,300. The structure present in the polymer 6 is represented by the following formula.

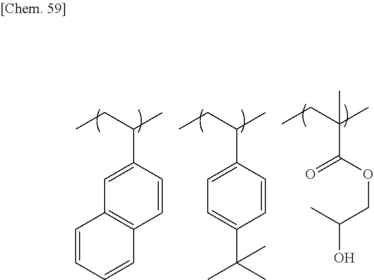

### Synthesis Example 7

In 40.00 g of propylene glycol monomethyl ether acetate, 5.00 g (molar ratio relative to the whole polymer 7: 55%) of 2-vinylnaphthalene, 2.91 g (molar ratio relative to the whole polymer 7: 26%) of 2-phenylethyl methacrylate, 1.61 g (molar ratio relative to the whole polymer 7: 19%) of 2-hydroxypropyl methacrylate, and 0.48 g of 2,2′-azobisisobutyronitrile were dissolved. A reaction vessel was purged with nitrogen, and then the solution was heated and stirred at 140° C. for about 4 hours. The reaction solution was added dropwise to methanol, and a precipitate was recovered by suction filtration and then dried at 60° C. under reduced pressure to recover a polymer 7. The weight average molecular weight Mw measured by GPC in terms of polystyrene was 6,600. The structure present in the polymer 7 is represented by the following formula.

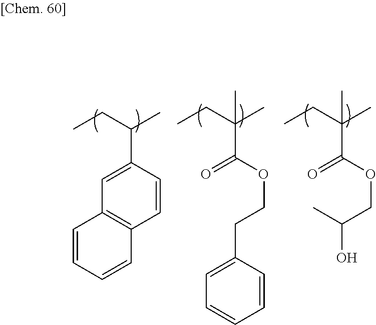

### Comparative Synthesis Example 1

To 682.00 g of propylene glycol monomethyl ether in a reaction vessel, 100.00 g of monoallyl diglycidyl isocyanurate (manufactured by Shikoku Chemicals Corporation), 66.4 g of 5,5-diethylbarbituric acid (manufactured by Tateyama Kasei Co., Ltd), and 4.1 g of benzyltriethylammonium chloride were added and dissolved. The reaction vessel was purged with nitrogen, and then a reaction was allowed to proceed at 130° C. for 24 hours to obtain a solution containing a comparative polymer 1. As a result of GPC analysis, the obtained comparative polymer 1 had a weight average molecular weight of 6,800 in terms of standard polystyrene. The structure present in the comparative polymer 1 is represented by the following formula.

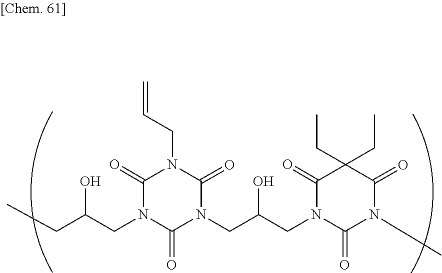

### Comparative Synthesis Example 2

In 40.00 g of propylene glycol monomethyl ether acetate, 7.25 g (molar ratio relative to the whole comparative polymer 2: 80%) of styrene, 2.51 g (molar ratio relative to the whole comparative polymer 2: 20%) of 2-hydroxypropyl methacrylate, and 0.24 g of 2,2′-azobisisobutyronitrile were dissolved. A reaction vessel was purged with nitrogen, and then the solution was heated and stirred at 140° C. for about 4 hours. The reaction solution was added dropwise to methanol, and a precipitate was recovered by suction filtration and then dried at 60° C. under reduced pressure to recover a comparative polymer 2. The weight average molecular weight Mw measured by GPC in terms of polystyrene was 13,000. The structure present in the comparative polymer 2 is represented by the following formula.

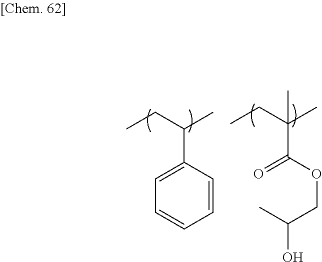

### Comparative Synthesis Example 3

In 40.00 g of propylene glycol monomethyl ether acetate, 5.62 g (molar ratio relative to the whole comparative polymer 3: 60%) of styrene, 1.80 g (molar ratio relative to the whole comparative polymer 3: 20%) of methyl methacrylate, 2.34 g (molar ratio relative to the whole comparative polymer 3: 20%) of 2-hydroxyethyl methacrylate, and 0.24 g of 2,2′-azobisisobutyronitrile were dissolved. A reaction vessel was purged with nitrogen, and then the solution was heated and stirred at 140° C. for about 4 hours. The reaction solution was added dropwise to methanol, and a precipitate was recovered by suction filtration and then dried at 60° C. under reduced pressure to recover a comparative polymer 3. The weight average molecular weight Mw measured by GPC in terms of polystyrene was 13,300. The structure present in the comparative polymer 3 is represented by the following formula.

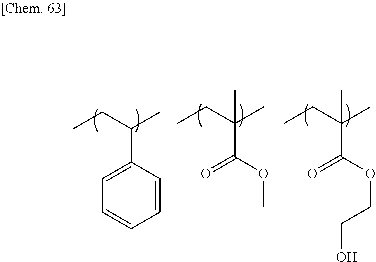

### (Preparation of Underlayer Film-Forming Composition)

The components were mixed in the proportions shown in Table 1, and the mixture was filtered using a polyethylene microfilter having a pore size of 0.05 μm to prepare underlayer film-forming compositions of Examples 1 to 7 and underlayer film-forming compositions of Comparative Examples 1 to 3, respectively.

Abbreviations in Table 1 are as follows.
PyPSA: pyridinium-p-hydroxybenzenesulfonic acid
PyPTS: pyridinium-p-toluenesulfonic acid
PGMEA: propylene glycol monomethyl ether acetate
PGME: propylene glycol monomethyl ether
PGME-PL: Imidazo[4,5-d]imidazole-2,5(1H,3H)-dione, tetrahydro-1,3,4,6-tetrakis[(2-methoxy-1-methylethoxy)methyl]-(the following structural formula)

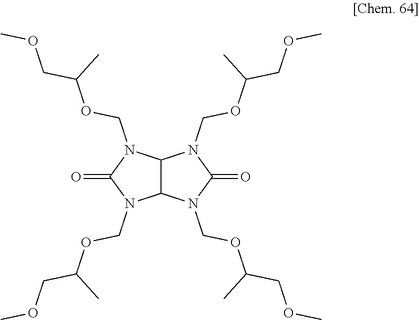

TMOM-BP: 3,3′,5,5′-tetrakis(methoxymethyl)-[1,1′-biphenyl]-4,4′-diol (trade name: TMOM-BP, manufactured by Honshu Chemical Industry Co., Ltd., substructural formula)

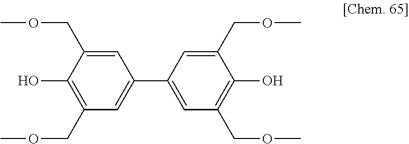

PL-LI: 1,3,4,6-tetrakis(methoxymethyl)glycoluril (the following structural formula)

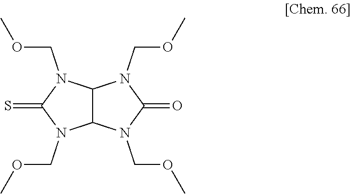

TABLE 1

| | | | | | | Film |
|---|---|---|---|---|---|---|
| | Component 1 | Component 2 | Curing catalyst | Solvent | | thickness |
| Example 1 | Polymer 1 | PGME-PL | PyPSA | PGME | PGMEA | 5 nm |
| (parts by | 0.151 | 0.043 | 0.008 | 30 | 70 | |
| mass) | | | | | | |
| Example 2 | Polymer 2 | PGME-PL | PyPSA | PGME | PGMEA | 5 nm |
| (parts by | 0.151 | 0.043 | 0.008 | 30 | 70 | |
| mass) | | | | | | |
| Example 3 | Polymer 3 | PGME-PL | PyPSA | PGME | PGMEA | 5 nm |
| (parts by | 0.151 | 0.043 | 0.008 | 30 | 70 | |
| mass) | | | | | | |
| Example 4 | Polymer 4 | PGME-PL | PyPSA | PGME | PGMEA | 5 nm |
| (parts by | 0.151 | 0.043 | 0.008 | 30 | 70 | |
| mass) | | | | | | |
| Example 5 | Polymer 5 | PL-LI | PyPTS | PGME | PGMEA | 6 nm |
| (parts by | 0.138 | 0.039 | 0.004 | 30 | 70 | |
| mass) | | | | | | |
| Example 6 | Polymer 6 | PL-LI | PyPTS | PGME | PGMEA | 6 nm |
| (parts by | 0.157 | 0.039 | 0.004 | 30 | 70 | |
| mass) | | | | | | |
| Example 7 | Polymer 7 | PL-LI | PyPTS | PGME | PGMEA | 6 nm |
| (parts by | 0.157 | 0.039 | 0.004 | 30 | 70 | |
| mass) | | | | | | |
| Comparative | Comparative | PGME-PL | PyPSA | PGME | PGMEA | 5 nm |
| Example 1 | Polymer 1 | | | | | |
| (parts by | 0.151 | 0.043 | 0.008 | 70 | 30 | |
| mass) | | | | | | |
| Comparative | Comparative | PL-LI | PyPTS | PGME | PGMEA | 6 nm |
| Example 2 | Polymer 2 | | | | | |
| (parts by | 0.157 | 0.039 | 0.004 | 30 | 70 | |
| mass) | | | | | | |
| Comparative | Comparative | PL-LI | PyPTS | PGME | PGMEA | 6 nm |
| Example 3 | Polymer 3 | | | | | |
| (parts by | 0.157 | 0.039 | 0.004 | 30 | 70 | |
| mass) | | | | | | |

### (Evaluation of Resist Patterning)

### <Formation of Underlayer Film>

Each of the underlayer film-forming compositions of Examples 1 to 7 and Comparative Examples 1 to 3 was applied onto a silicon wafer using a spinner. The silicon wafer was baked on a hot plate at 205 to 250° C. for 60 seconds to obtain underlayer films of Examples 1 to 7 and Comparative Examples 1 to 3. The film thickness thereof is shown in Table 1. The film thickness was measured using an ellipsometric film thickness measurement system RE-3100 (SCREEN Semiconductor Solutions Co., Ltd.).

### <Test for Resist Pattern Formation by Electron Beam Lithography Apparatus>

An EUV positive resist solution was spin-coated on each of the underlayer films of Examples 1 to 7 and Comparative Examples 1 to 3, and heated at 130° C. for 60 seconds to form an EUV resist film having a film thickness of 35 nm. The resist films were exposed under the predetermined conditions using an electron beam lithography system (ELS-G130). After the exposure, the silicon wafer was baked (PEB) at 90° C. for 60 seconds, cooled on a cooling plate to room temperature, and subjected to puddle developing for 30 seconds using a 2.38% aqueous tetramethylammonium hydroxide solution (trade name NMD-3 manufactured by Tokyo Ohka Kogyo Co., Ltd.) as a photoresist developer. A resist pattern having a line size of 16 nm to 28 nm was formed. A scanning electron microscope (CG4100 manufactured by Hitachi High-Technologies Corporation) was used to measure the length of the resist pattern.

The photoresist pattern thus obtained was observed from the upper part of the pattern. The amount of charge for forming 22 nm line/44 nm pitch (line-and-space (L/S=1/1)) was defined as the optimum irradiation energy, and LWR which is a value indicating the roughness of the pattern shape at that time was checked. The LWR indicates a triple value (3σ) (unit: nm) of a standard deviation (σ) obtained from the measurement results at 400 line positions in the longitudinal direction of the line with a scanning electron microscope (CG4100, manufactured by Hitachi High-Tech Corporation). A smaller value of LWR indicates that a pattern capable of forming a favorable pattern is formed. The results are shown in Table 2.

### (Evaluation of Self-Assembly of Block Copolymers)

### <Preparation of Self-Assembled Film-Forming Composition 1>

In 24.5 g of propylene glycol monomethyl ether acetate, 0.5 g of a polystyrene/poly(methyl methacrylate) copolymer (manufactured by Polymer Source, Inc., PS (Mw: 22,000, Mn: 21,000)-b-PMMA (Mw: 22,900, Mn: 21,000), polydispersity=1.07) which is a block copolymer 1 was dissolved to form a 2 mass % solution, and then the solution was filtered using a polyethylene microfilter having a pore size of 0.02 μm to prepare a self-assembled film-forming composition 1 containing the block copolymer 1 (BCP1).

### <Preparation of Self-Assembled Film-Forming Composition 2>

A self-assembled film-forming composition 2 containing a block copolymer 2 (BCP2) was prepared in the same manner as in the preparation of the self-assembled film-forming composition 1 except that polystyrene/poly(methyl methacrylate) copolymer (manufactured by Polymer Source, Inc., PS (Mw: 39,800, Mn: 37,500)-b-PMMA (Mw: 19,100, Mn: 18,000), polydispersity=1.06) which is the block copolymer 2 was used in place of the block copolymer 1 in the preparation of the self-assembled film-forming composition 1.

### <Induction of Microphase Separation Structure>

Each of the underlayer film-forming compositions of Examples 1 to 7 and Comparative Examples 1 to 3 was applied onto a silicon wafer and baked on a hot plate at 205 to 250° C. for 60 seconds to obtain underlayer films of Examples 1 to 7 and Comparative Examples 1 to 3. The film thickness thereof is shown in Table 1. The self-assembled film-forming composition 1 or the self-assembled film-forming composition 2 was applied thereon by a spin coater, and heated on a hot plate at 100° C. for 1 minute to form a self-assembled film having a film thickness of 40 nm. The wafer on which the self-assembled film was formed was heated at 260° C. for 15 minutes under a N₂ gas atmosphere to induce a microphase separation structure of the self-assembled film.

### <Observation of Microphase Separation Structure>

The silicon wafer in which the microphase separation structure was induced was etched for 3 seconds using an etching apparatus (Lam 2300 Versys Kiyo 45) manufactured by Lam Research Co., Ltd. and using O₂/N₂ gas as an etching gas, so that a poly(methyl methacrylate) region was preferentially etched, and subsequently the shape was observed with an electron microscope (S-4800, manufactured by Hitachi High-Technologies Corporation).

### <Checking of Block Copolymer Alignability>

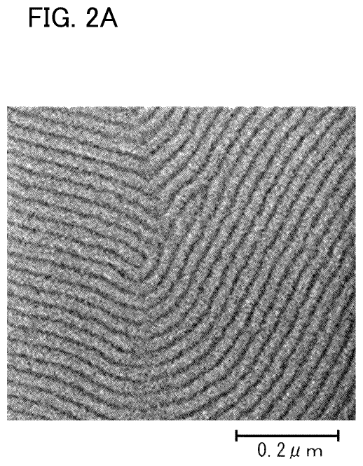

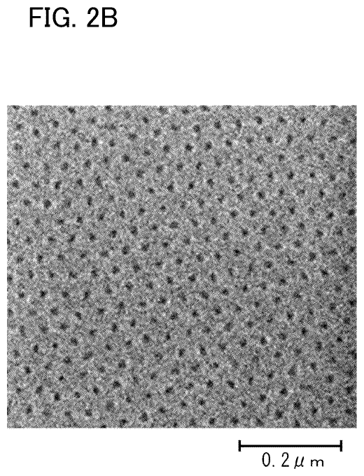

The alignability of the block copolymers (BCP1, BCP2) prepared in Examples 1 to 7 and Comparative Examples 1 to 3 was checked. The results are shown in Table 2, and FIGS. 2A, 2B, 3A, 3B, 4A, and 4B show cases of vertical alignment (vertically aligned lamella structures) and alignment failure of the electron microscope observation results (magnification: 200 K). In Table 2, “Vertical alignment” means “vertically aligned lamella or cylinder structures”.

FIG. 2A is an electron microscope (SEM) photograph of a microphase separation structure of a self-assembled film prepared using the self-assembled film-forming composition 1 in Example 1.

FIG. 2B is an SEM photograph of a microphase separation structure of a self-assembled film prepared using the self-assembled film-forming composition 2 in Example 1.

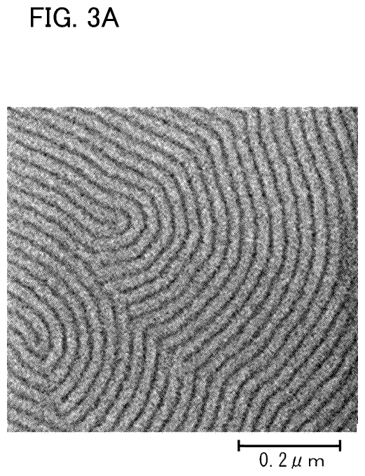

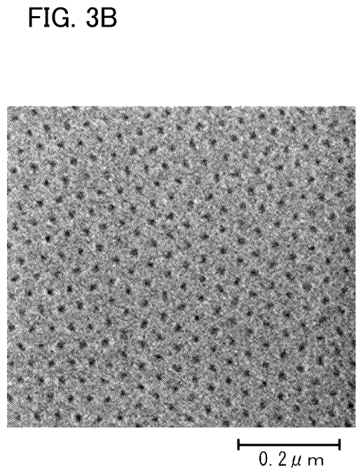

FIG. 3A is an SEM photograph of a microphase separation structure of a self-assembled film prepared using the self-assembled film-forming composition 1 in Example 2.

FIG. 3B is an SEM photograph of a microphase separation structure of a self-assembled film prepared using the self-assembled film-forming composition 2 in Example 2.

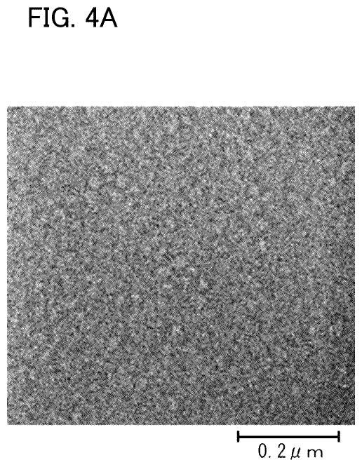

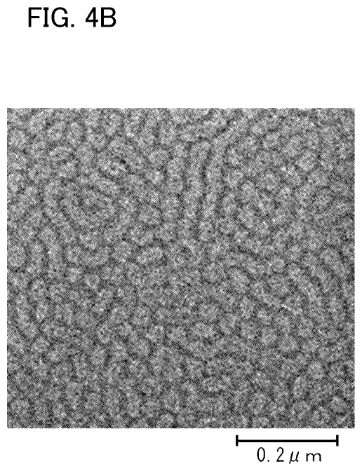

FIG. 4A is an SEM photograph of a microphase separation structure of a self-assembled film prepared using the self-assembled film-forming composition 1 in Comparative Example 1.

FIG. 4B is an SEM photograph of a microphase separation structure of a self-assembled film prepared using the self-assembled film-forming composition 2 in Comparative Example 1.

TABLE 2

| | Lithography | BCP1 | BCP2 |
|---|---|---|---|
| | results | alignment | alignment |
| | LWR (nm) | results | results |
| Example 1 | 3.24 | Vertical alignment | Vertical alignment |
| Example 2 | 3.20 | Vertical alignment | Vertical alignment |
| Example 3 | 3.25 | Vertical alignment | Vertical alignment |
| Example 4 | 3.25 | Vertical alignment | Vertical alignment |
| Example 5 | 3.20 | Vertical alignment | Vertical alignment |
| Example 6 | 3.33 | Vertical alignment | Vertical alignment |
| Example 7 | 3.21 | Vertical alignment | Vertical alignment |
| Comparative | 3.49 | Alignment failure | Alignment failure |
| Example 1 | | | |
| Comparative | 3.48 | Vertical alignment | Vertical alignment |
| Example 2 | | | |
| Comparative | 3.47 | Vertical alignment | Alignment failure |
| Example 3 | | | |

### REFERENCE SIGNS LIST

1 Semiconductor substrate
2 Underlayer film
3 Resist film
4 Brush layer
5 Self-assembled film
5a Domain of block A
5b Domain of block B

1. An underlayer film, which is a baked product of a coating film of an underlayer film-forming composition, wherein
in lithography using a resist film of either a photoresist film or an electron beam resist film and a self-assembled film, the underlayer film is used as an underlayer film of the resist film, and then is further used as an underlayer film of the self-assembled film,
the underlayer film-forming composition contains a polymer and a crosslinking agent,
the polymer has a unit structure (A) having a polycyclic aromatic structure and a unit structure (B) having a reactive group, and
the crosslinking agent has a functional group that can react with the reactive group.

2. The underlayer film according to claim 1, wherein the unit structure (A) is a unit structure represented by formula (A-1) below: 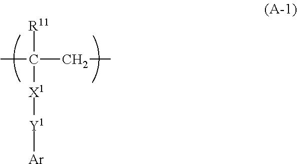
in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted.

3. The resist underlayer film according to claim 1, wherein the unit structure (B) is at least one of a unit structure represented by formula (B-1) below and a unit structure represented by formula (B-2) below: 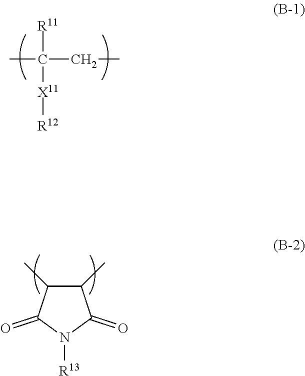
in formula (B-1), R¹¹ represents a hydrogen atom or a methyl group, X¹¹ represents an ester group or an amide group, and R¹² represents a monovalent group having 1 to 12 carbon atoms and having the reactive group, and
in formula (B-2), R¹³ represents a monovalent group having 1 to 12 carbon atoms and having the reactive group.

4. The underlayer film according to claim 1, wherein the polymer further has a unit structure (C) of at least one of a unit structure (C-1) having a monocyclic aromatic structure and a unit structure (C-2) derived from a maleimide structure.

5. The underlayer film according to claim 4, wherein
the unit structure (C-1) is a unit structure represented by formula (C-1-1) below, and
the unit structure (C-2) is a unit structure represented by formula (C-2-1) below: 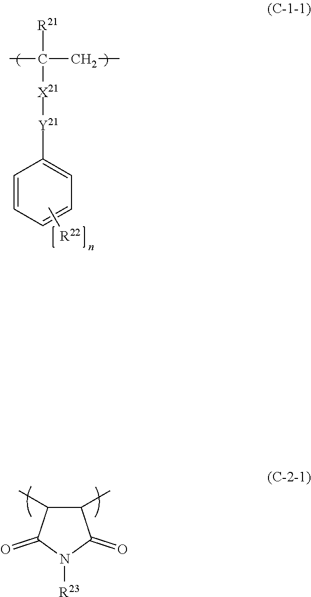
in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.

6. The underlayer film according to claim 1, wherein a molar ratio of the unit structure (A) to all unit structures of the polymer is 40 mol % or more.

7. The underlayer film according to claim 1, wherein a molar ratio of the unit structure (B) to all unit structures of the polymer is 5 mol % to 40 mol %.

8. The underlayer film according to claim 1, wherein
the polymer further has a unit structure (C) of at least one of a unit structure (C-1) having a monocyclic aromatic structure and a unit structure (C-2) derived from a maleimide structure,
the unit structure (A) is a unit structure represented by formula (A-1) below,
the unit structure (B) is at least one of a unit structure represented by formula (B-1) below and a unit structure represented by formula (B-2) below,
the unit structure (C-1) is a unit structure represented by formula (C-1-1) below,
the unit structure (C-2) is a unit structure represented by formula (C-2-1) below,
a molar ratio of the unit structure (A) to all unit structures of the polymer is 40 mol % or more, and
a molar ratio of the unit structure (B) to all unit structures of the polymer is 5 mol % to 40 mol %: 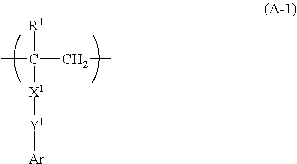
in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted, 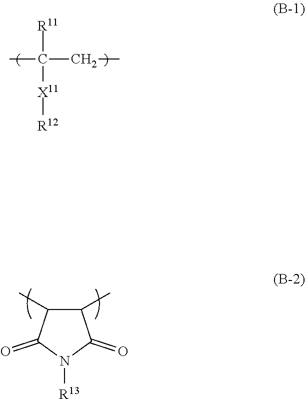
in formula (B-1), R¹¹ represents a hydrogen atom or a methyl group, X¹¹ represents an ester group or an amide group, and R¹² represents a monovalent group having 1 to 6 carbon atoms and having the reactive group, and
in formula (B-2), R¹³ represents a monovalent group having 1 to 6 carbon atoms and having the reactive group, 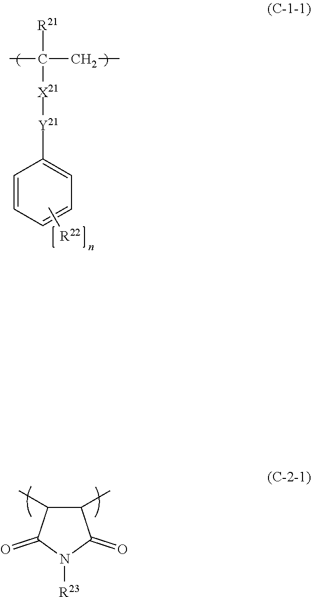
in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.

9. The underlayer film according to claim 1, wherein a content of the crosslinking agent in the underlayer film-forming composition is 20 mass % to 50 mass % of the polymer.

10. The underlayer film according to claim 1, wherein the self-assembled film is a film containing a block copolymer.

11. The underlayer film according to claim 1, wherein a film thickness is less than 10 nm.

12. An underlayer film-forming composition for forming an underlayer film that is used, in lithography using a resist film of either a photoresist film or an electron beam resist film and a self-assembled film, as an underlayer film of the resist film, and then is further used as an underlayer film of the self-assembled film,
the underlayer film-forming composition comprising a polymer and a crosslinking agent, wherein
the polymer has a unit structure (A) having a polycyclic aromatic structure and a unit structure (B) having a reactive group, and
the crosslinking agent has a functional group that can react with the reactive group.

13. The underlayer film-forming composition according to claim 12, wherein the unit structure (A) is a unit structure represented by formula (A-1) below: 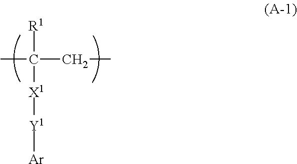
in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted.

14. The underlayer film-forming composition according to claim 12, wherein the unit structure (B) is at least one of a unit structure represented by formula (B-1) below and a unit structure represented by formula (B-2) below: 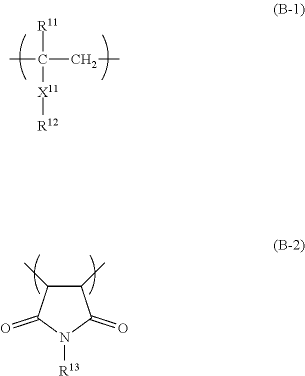
in formula (B-1), R¹¹ represents a hydrogen atom or a methyl group, X¹¹ represents an ester group or an amide group, and R¹² represents a monovalent group having 1 to 12 carbon atoms and having the reactive group, and
in formula (B-2), R¹³ represents a monovalent group having 1 to 12 carbon atoms and having the reactive group.

15. The underlayer film-forming composition according to claim 12, wherein the polymer further has a unit structure (C) of at least one of a unit structure (C-1) having a monocyclic aromatic structure and a unit structure (C-2) derived from a maleimide structure.

16. The underlayer film-forming composition according to claim 15, wherein
the unit structure (C-1) is a unit structure represented by formula (C-1-1) below, and
the unit structure (C-2) is a unit structure represented by formula (C-2-1) below: 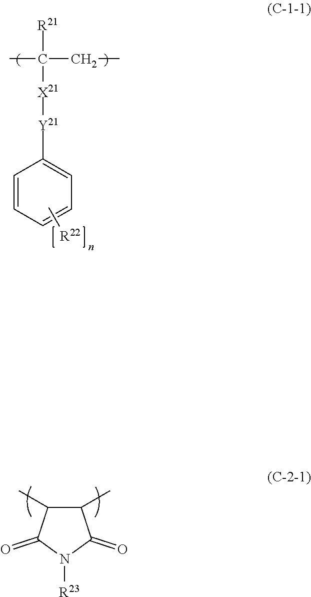
in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.

17. The underlayer film-forming composition according to claim 12, wherein a molar ratio of the unit structure (A) to all unit structures of the polymer is 40 mol % or more.

18. The underlayer film-forming composition according to claim 12, wherein a molar ratio of the unit structure (B) to all unit structures of the polymer is 5 mol % to 40 mol %.

19. The underlayer film-forming composition according to claim 12, wherein
the polymer further has a unit structure (C) of at least one of a unit structure (C-1) having a monocyclic aromatic structure and a unit structure (C-2) derived from a maleimide structure,
the unit structure (A) is a unit structure represented by formula (A-1) below,
the unit structure (B) is at least one of a unit structure represented by formula (B-1) below and a unit structure represented by formula (B-2) below,
the unit structure (C-1) is a unit structure represented by formula (C-1-1) below,
the unit structure (C-2) is a unit structure represented by formula (C-2-1) below,
a molar ratio of the unit structure (A) to all unit structures of the polymer is 40 mol % or more, and
a molar ratio of the unit structure (B) to all unit structures of the polymer is 5 mol % to 40 mol %: 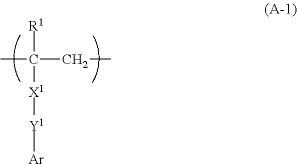
in formula (A-1), R¹ represents a hydrogen atom or a methyl group, X¹ represents a single bond, an ester group, or an amide group, Y¹ represents a single bond or an alkylene group having 1 to 6 carbon atoms, and Ar represents a monovalent group that is obtained by removing a hydrogen atom from naphthalene, anthracene, phenanthrene, pyrene, triphenylene, chrysene, naphthacene, biphenylene, fluorene, or carbazole and may be substituted, 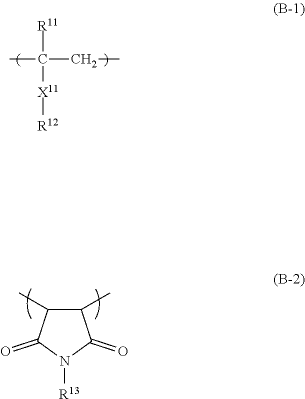
in formula (B-1), R¹¹ represents a hydrogen atom or a methyl group, X¹¹ represents an ester group or an amide group, and R¹² represents a monovalent group having 1 to 6 carbon atoms and having the reactive group, and
in formula (B-2), R¹³ represents a monovalent group having 1 to 6 carbon atoms and having the reactive group, 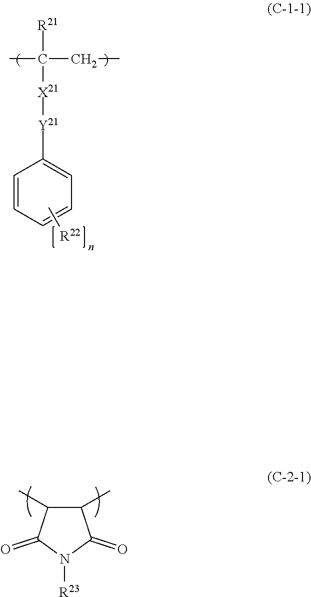
in formula (C-1-1), R²¹ represents a hydrogen atom or a methyl group, X²¹ represents a single bond, an ester group, or an amide group, Y²¹ represents a single bond or an alkylene group having 1 to 6 carbon atoms, R²² represents a halogen atom, an alkyl group that has 1 to 6 carbon atoms and may be substituted with a halogen atom, or an alkoxy group that has 1 to 6 carbon atoms and may be substituted with a halogen atom, n represents an integer of 0 to 5, and when there are two or more R²²'s, the two or more R²²'s may be identical or different, and
in formula (C-2-1), R²³ represents a hydrogen atom, an alkyl group that has 1 to 10 carbon atoms and may be substituted with a halogen atom, or an aryl group that has 6 to 10 carbon atoms and may be substituted with a halogen atom.

20. The underlayer film-forming composition according to claim 12, wherein a content of the crosslinking agent is 20 mass % to 50 mass % of the polymer.

21. The underlayer film-forming composition according to claim 12, wherein the self-assembled film is a film containing a block copolymer.

22. The underlayer film-forming composition according to claim 12, wherein a film thickness of the underlayer film is less than 10 nm.

23. A method for producing a semiconductor element, the method comprising:
a step of forming an underlayer film on a semiconductor substrate using the underlayer film-forming composition according to claim 12;
a step of forming a resist film of either a photoresist film or an electron beam resist film on the underlayer film;
a step of obtaining a resist pattern by irradiating the resist film with light or an electron beam, and then developing the resist film;
a step of forming a patterned underlayer film by etching the underlayer film using the resist pattern as a mask; and
a step of forming a self-assembled film on the patterned underlayer film.

24. The method for producing a semiconductor element according to claim 23, further comprising a step of forming a brush layer in a gap in a pattern of the patterned underlayer film between the step of forming a patterned underlayer film and the step of forming a self-assembled film.

25. The method for producing a semiconductor element according to claim 23, wherein the self-assembled film is a film containing a block copolymer.

26. The method for producing a semiconductor element according to claim 23, further comprising a step of removing the resist pattern after the step of forming a patterned underlayer film.
